(19) United States
(12) Patent Application Publication
(10) Pub. No.: US 2022/0271054 A1
(43) Pub. Date: Aug. 25, 2022

(54) SEMICONDUCTOR MEMORY DEVICE

(71) Applicant: Kioxia Corporation, Tokyo (JP)

(72) Inventor: Satoshi NAGASHIMA, Yokkaichi Mie (JP)

(73) Assignee: Kioxia Corporation, Tokyo (JP)

(21) Appl. No.: 17/397,376

(22) Filed: Aug. 9, 2021

(30) Foreign Application Priority Data
Feb. 19, 2021 (JP) 2021-25717

(51) Int. Cl. H01L 27/11582; H01L 27/11556

(52) U.S. Cl. CPC H01L 27/11582; H01L 27/11556

(57) ABSTRACT

A semiconductor memory device includes a semiconductor substrate extending in a first and a second directions, memory blocks arranged in the first direction, and an inter-block structure disposed between the memory blocks. The memory block includes conductive layers, first semiconductor layers, and electric charge accumulating portions. The conductive layers are arranged in the third direction, and extend in the second direction. The first semiconductor layers extend in the third direction and are opposed to the conductive layers. The electric charge accumulating portions are disposed between the conductive layers and the first semiconductor layers. The inter-block structure includes a second semiconductor layer extending in the second direction and the third direction. The first semiconductor layers and second semiconductor layers are a part of the semiconductor substrate.

### CROSS-REFERENCE TO RELATED APPLICATIONS

This application is based upon and claims the benefit of Japanese Patent Application No. 2021-25717, filed on Feb. 19, 2021, the entire contents of which are incorporated herein by reference.

### BACKGROUND

### Field

This embodiment relates to a semiconductor memory device.

### Description of the Related Art

There has been known a semiconductor memory device including a substrate, a plurality of conductive layers stacked in a direction intersecting with a surface of the substrate, a semiconductor layer opposed to the plurality of conductive layers, and a gate insulating layer disposed between the conductive layers and the semiconductor layer. The gate insulating layer includes a memory unit configured to store data. The memory unit is, for example, an insulating electric charge accumulating layer of silicon nitride (Si₃N₄) or the like and a conductive electric charge accumulating layer, such as a floating gate.

### BRIEF DESCRIPTION OF THE DRAWINGS

FIG. 1 is a schematic plan view of a semiconductor memory device according to a first embodiment;

FIG. 2 is a schematic plan view of the semiconductor memory device;

FIG. 3 is a schematic plan view of the semiconductor memory device;

FIG. 4 is a schematic perspective view of the semiconductor memory device;

FIG. 5 is a schematic cross-sectional view of the semiconductor memory device;

FIG. 6 is a schematic cross-sectional view of the semiconductor memory device;

FIG. 7 is a schematic plan view for describing a manufacturing method for the semiconductor memory device;

FIG. 8 is a schematic cross-sectional view for describing the manufacturing method;

FIG. 9 is a schematic cross-sectional view for describing the manufacturing method;

FIG. 10 is a schematic plan view for describing the manufacturing method;

FIG. 11 is a schematic cross-sectional view for describing the manufacturing method;

FIG. 12 is a schematic plan view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic plan view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic plan view for describing the manufacturing method;

FIG. 32 is a schematic cross-sectional view for describing the manufacturing method;

FIG. 33 is a schematic cross-sectional view for describing the manufacturing method;

FIG. 34 is a schematic plan view for describing the manufacturing method;

FIG. 35 is a schematic cross-sectional view for describing the manufacturing method;

FIG. 36 is a schematic cross-sectional view for describing the manufacturing method;

FIG. 37 is a schematic plan view of a semiconductor memory device according to a second embodiment;

FIG. 38 is a schematic cross-sectional view of the semiconductor memory device;

FIG. 39 is a schematic cross-sectional view of the semiconductor memory device;

FIG. 40 is a schematic plan view for describing a manufacturing method for the semiconductor memory device;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic plan view of a semiconductor memory device according to a third embodiment;

FIG. 52 is a schematic cross-sectional view of the semiconductor memory device;

FIG. 53 is a schematic cross-sectional view for describing a method for manufacturing the semiconductor memory device;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view of a semiconductor memory device according to another embodiment.

FIG. 59 is a schematic plan view of a semiconductor memory device according to another embodiment; and

FIG. 60 is a schematic cross-sectional view of a semiconductor memory device according to another embodiment.

### DETAILED DESCRIPTION

A semiconductor memory device according to one embodiment comprises: a semiconductor substrate extending in a first direction and a second direction intersecting with the first direction; a plurality of memory blocks arranged in the first direction; and an inter-block structure disposed between the plurality of memory blocks. The memory block includes: a plurality of conductive layers arranged in a third direction intersecting with the first direction and the second direction, the plurality of conductive layers extending in the second direction; a plurality of first semiconductor layers that extend in the third direction and are opposed to the plurality of conductive layers; and a plurality of electric charge accumulating portions disposed between the plurality of conductive layers and the plurality of first semiconductor layers. The inter-block structure includes a second semiconductor layer extending in the second direction and the third direction, and the plurality of first semiconductor layers and the second semiconductor layer are parts of the semiconductor substrate.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached with same reference numerals and their descriptions may be omitted.

In this specification, when referring to a “semiconductor memory device”, it may mean a memory die and may mean a memory system including a controller die, such as a memory chip, a memory card, and a Solid State Drive (SSD) . Further, it may mean a configuration including a host computer, such as a smartphone, a tablet terminal, and a personal computer.

In this specification, a direction parallel to a front surface of the substrate is referred to as an X-direction, a direction parallel to the front surface of the substrate and perpendicular to the X-direction is referred to as a Y-direction, and a direction perpendicular to the front surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on a back surface of the substrate. For example, a direction away from the back surface of the substrate along the Z-direction is referred to as above and a direction approaching the back surface of the substrate along the Z-direction is referred to as below. A lower surface and a lower end of a certain configuration mean a surface and an end portion at the back surface side of the substrate side of this configuration. An upper surface and an upper end of a certain configuration mean a surface and an end portion at a side opposite to the back surface of the substrate of this configuration. A surface intersecting with the X-direction or the Y-direction is referred to as a side surface and the like.

In this specification, when referring to a “width”, a “length”, a “thickness”, or the like in a predetermined direction of a configuration, a member, or the like, this may mean a width, a length, a thickness, or the like in a cross-sectional surface or the like observed with a Scanning electron microscopy (SEM) , a Transmission electron microscopy (TEM) , or the like.

[First Embodiment]

[Configuration]

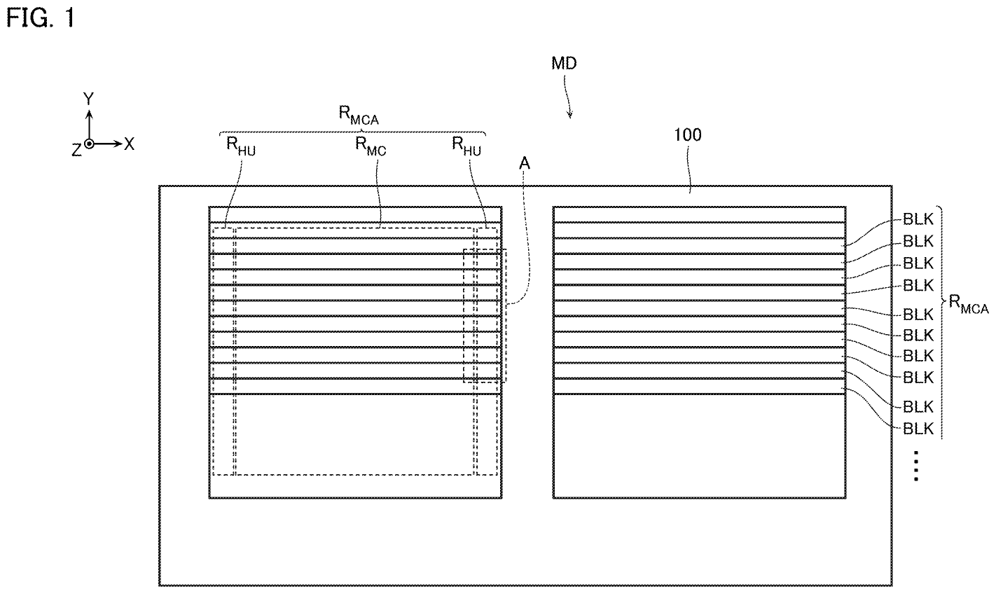

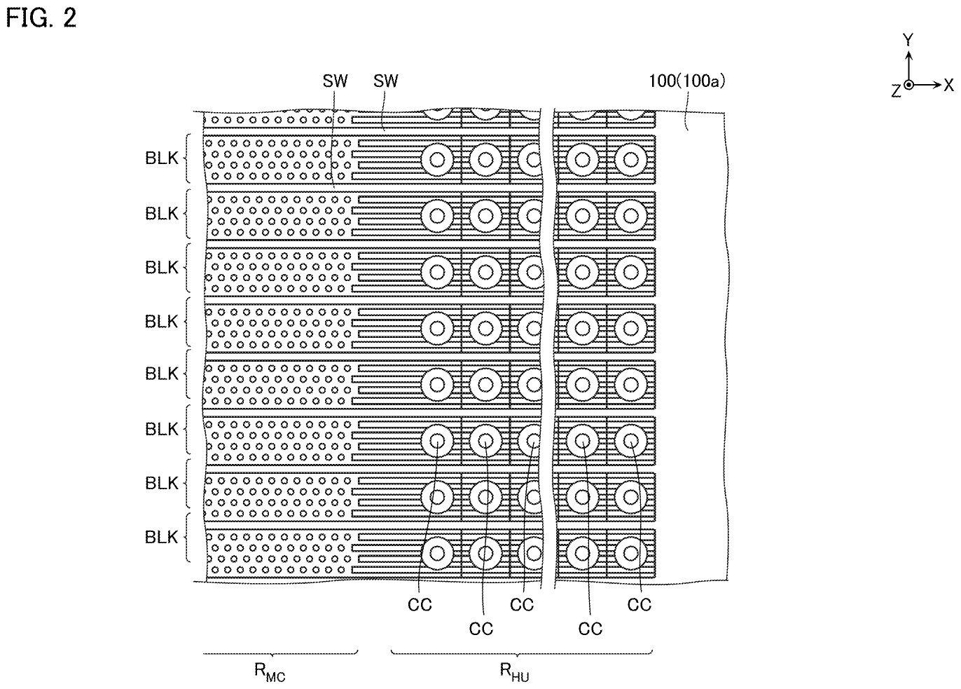

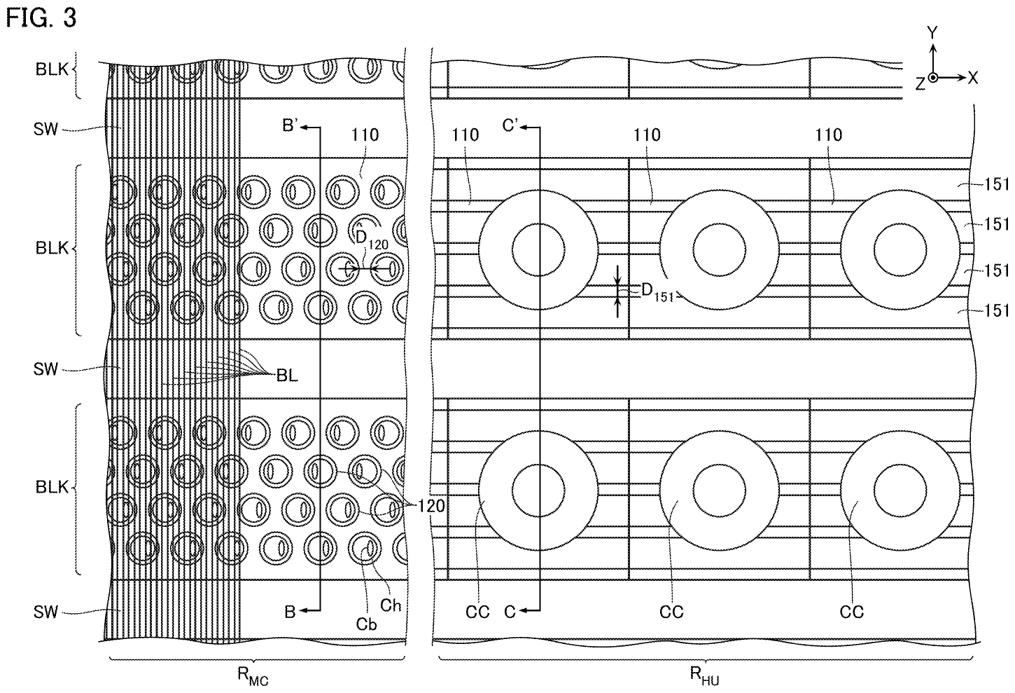

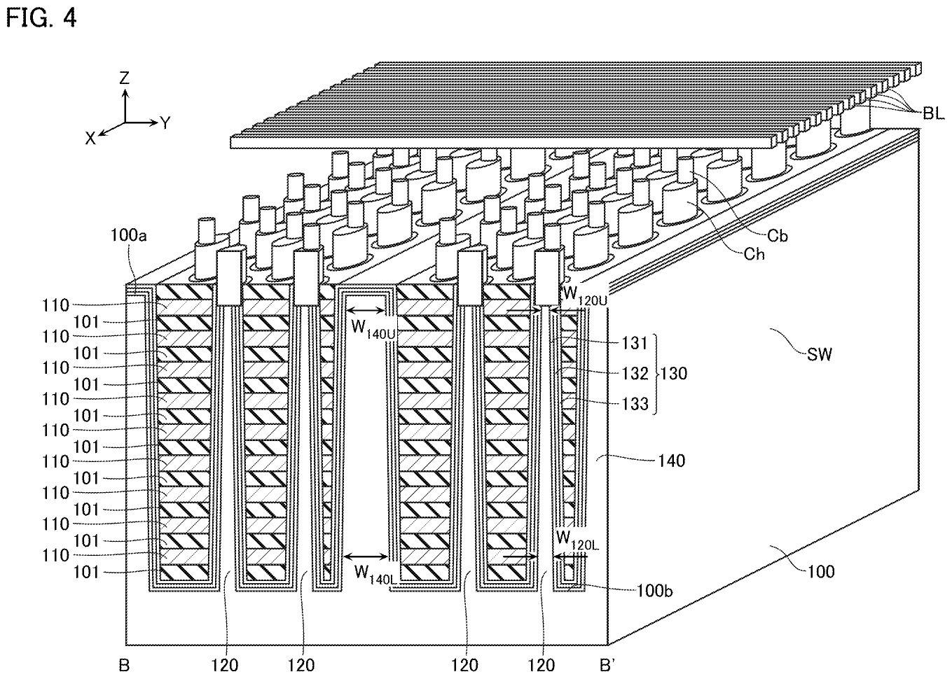

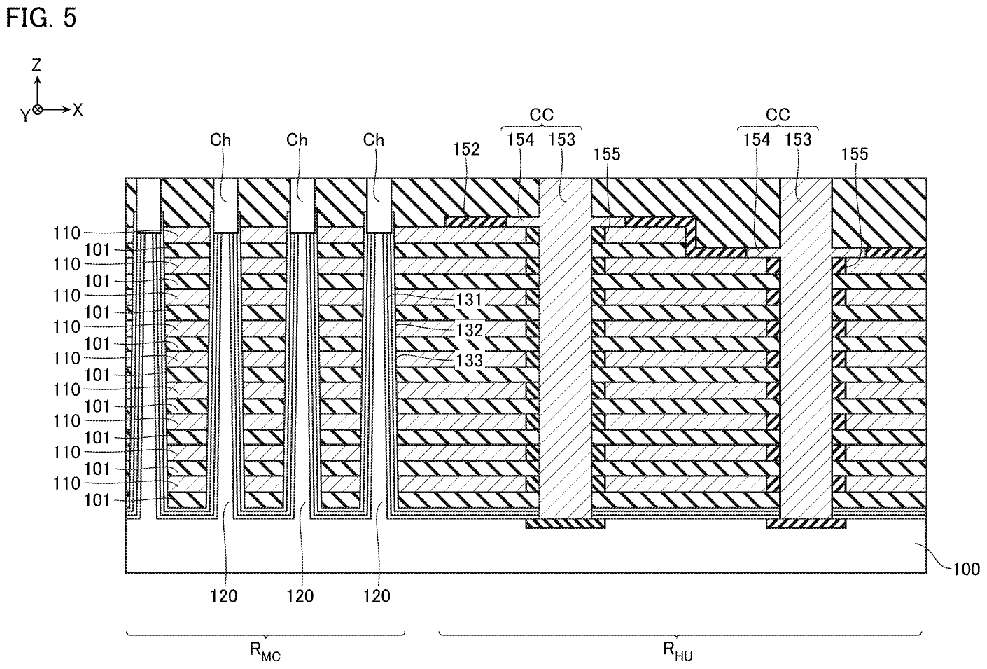

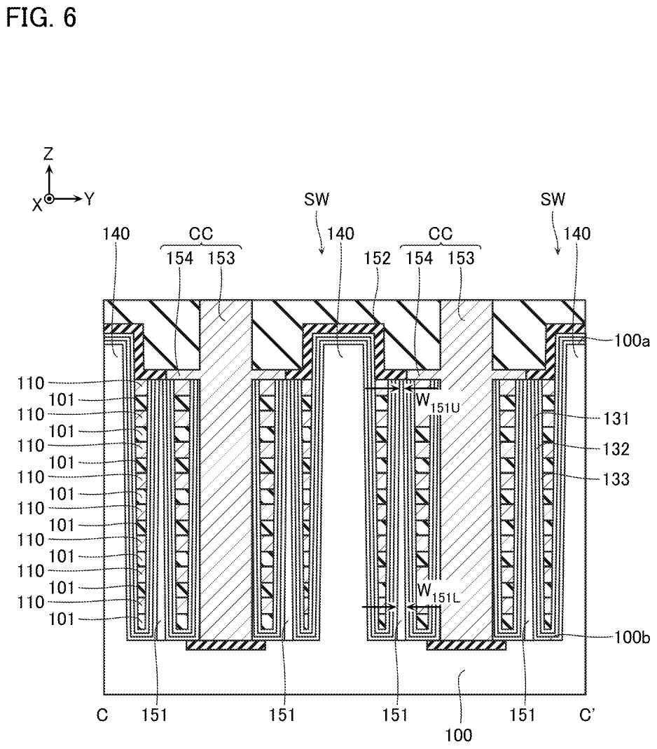

FIG. 1 is a schematic plan view of a memory die MD according to the first embodiment. FIG. 2 is a schematic plan view illustrating an enlarged part indicated by A in FIG. 1. FIG. 3 is a schematic plan view illustrating an enlarged part in FIG. 2. FIG. 4 is a schematic perspective view illustrating a configuration of a part of the memory die MD. FIG. 4 includes a schematic cross-section of the configuration illustrated in FIG. 3, taken along the line B-B′ and viewed along the arrow-direction. FIG. 5 is a schematic cross-sectional view illustrating a part of the configuration of the memory die MD. FIG. 6 is a schematic cross-sectional view of the configuration illustrated in FIG. 3, taken along the line C-C′ and viewed along the arrow-direction.

As illustrated in FIG. 1, the memory die MD includes a semiconductor substrate 100. The semiconductor substrate 100 is a semiconductor substrate of, for example, P-type single-crystal silicon (Si) containing P-type impurities, such as boron (B). As illustrated in FIG. 4, for example, the upper surface (front surface) of the semiconductor substrate 100 includes a surface 100a and a surface 100b. The surface 100b is disposed below the surface 100a.

In the illustrated example of FIG. 1, the semiconductor substrate 100 includes two memory cell array regions R_{MCA} arranged in the X-direction. The memory cell array region R_{MCA} includes a plurality of memory blocks BLK arranged in the Y-direction. Also, as illustrated in FIG. 2 and FIG. 3, an inter-block structure SW is disposed between two memory blocks BLK adjacent in the Y-direction.

The memory cell array region R_{MCA} includes a memory cell region R_{MC}, and a hook-up region R_{HU} arranged in the X-direction with respect to the memory cell region R_{MC}. Apart of the memory block BLK is disposed in the memory cell region R_{MC}. Also, a part of the memory block BLK is disposed in the hook-up region R_{HU}.

[Configuration of Memory Block BLK in Memory Cell Region R_{MC}]

As illustrated in FIG. 4, for example, the memory cell region R_{MC} of the memory block BLK includes a plurality of conductive layers 110 arranged in the Z-direction, a plurality of semiconductor layers 120 extending in the Z-direction, and gate insulating films 130. The gate insulating films 130 are disposed between the plurality of conductive layers 110 and the plurality of semiconductor layers 120.

Each of the plurality of conductive layers 110 functions as gate electrodes of memory transistors (memory cells) and a word line, or gate electrodes of select transistors and a select gate line. The plurality of conductive layers 110 are disposed below the surface 100a and above the surface 100b. A conductive layer 110 is an approximately plate-shaped conductive layer extending in the X-direction. The conductive layer 110 may contain tungsten (W) , molybdenum (Mo) , or polycrystalline silicon and the like containing impurities, such as phosphorus (P) or boron (B) . Also, the conductive layer 110 may include a barrier conductive film of titanium nitride (TiN) and the like, or may be without a barrier conductive film of titanium nitride (TiN) and the like. Between the plurality of conductive layers 110 arranged in the Z-direction, insulating layers 101 of silicon oxide (SiO₂) and the like are disposed.

The semiconductor layers 120 function as channel regions of the plurality of memory transistors (memory cells) and the select transistors arranged in the Z-direction. As illustrated in FIG. 3, for example, the semiconductor layers 120 are arranged in the X-direction and the Y-direction in a predetermined pattern. In FIG. 3, the distance between two semiconductor layers 120 adjacent in any direction in the XY plane is denoted by distance D₁₂₀.

As illustrated in FIG. 4, for example, the semiconductor layer 120 is a semiconductor layer in an approximately columnar shape. The outer peripheral surfaces of the semiconductor layers 120 are each surrounded by the conductive layers 110 and are opposed to the conductive layers 110.

The semiconductor layer 120 is, for example, a part of the semiconductor substrate 100. For example, the semiconductor layer 120 is of P-type single-crystal silicon. Also, a crystal orientation of the semiconductor layer 120 matches a crystal orientation of the rest of the semiconductor substrate 100.

An impurity region containing N-type impurities, such as phosphorus (P), is disposed in an upper end portion of the semiconductor layer 120. The impurity region is connected to the bit line BL via a contact electrode Ch and a contact electrode Cb.

A height position of the upper end of the semiconductor layer 120 may be approximately the same as that of the surface 100a. The height position of the upper end of the semiconductor layer 120 maybe lower than that of the surface 100a. The lower end of the semiconductor layer 120 is connected to the surface 100b of the semiconductor substrate 100.

The widths in the X-direction and Y-direction of a lower end portion of the semiconductor layer 120 may be equal to or greater than the widths in the X-direction and Y-direction of the upper end portion of the semiconductor layer 120. In the illustrated example, a width in the Y-direction of the portion of the semiconductor layer 120, opposed to the uppermost conductive layer 110, is denoted by width W_{120U}, and a width in the Y-direction of the portion of the semiconductor layer 120, opposed to the lowermost conductive layer 110, is denoted by width W_{120L}. The width W_{120L} is greater than the width W_{120U}. However, the width W_{120L} may be the same as the width W_{120U}.

The gate insulating film 130 has a substantially cylindrical shape covering the outer peripheral surface of the semiconductor layer 120. In the gate insulating film 130, portions disposed between the conductive layers 110 and the semiconductor layer 120 each function as an electric charge accumulating portion for the memory transistor (memory cell). The gate insulating film 130 includes a tunnel insulating film 131, an electric charge accumulating film 132, a block insulating film 133, which are stacked between the semiconductor layer 120 and the conductive layers 110. The tunnel insulating film 131 may include, for example, a stacked film of silicon oxide (SiO₂), silicon nitride (Si₃N₄), silicon oxide (SiO₂), and the like. The electric charge accumulating film 132 may be, for example, a film of silicon nitride (Si₃N₄) or the like that can accumulate an electric charge. The block insulating film 133, for example, may include a stacked film of silicon oxide (SiO₂) and alumina (Al₂O₃).

[Configuration of Memory Block BLK in Hook-Up Region R_{HU}]

As illustrated in FIG. 3, for example, the hook-up region R_{Hu} of the memory block BLK includes a plurality of insulating layers 151 arranged in the Y-direction. In FIG. 3, a distance between two insulating layers 151 adjacent in the Y-direction is denoted by distance D₁₅₁. The distance D₁₅₁ may be approximately the same as the distance D₁₂₀. For example, in a cross-sectional surface as shown in FIG. 3, the distance D₁₅₁ may be greater than 50% and smaller than 400% of the distance D₁₂₀.

The insulating layer 151 contains silicon oxide (SiO₂) or the like. The insulating layer 151 extends in the Z-direction and the X-direction.

For example, as illustrated in FIG. 6, a height position of the upper end of the insulating layer 151 is approximately the same as a height position of the upper surface of any of the plurality of conductive layers 110 arranged in the Z-direction. The lower end of the insulating layer 151 is connected to the surface 100b of the semiconductor substrate 100.

A width in the Y-direction of the lower end portion of the insulating layer 151 may be greater than a width in the Y-direction of the upper end portion of the insulating layer 151. In the illustrated example, the width in the Y-direction of a portion of the insulating layer 151, opposed to the uppermost conductive layer 110 in the cross section illustrated in FIG. 6, is denoted by width W_{151U}. A width in the Y-direction of the portion of the insulating layer 151, opposed to the lowermost conductive layer 110, is denoted by width W_{151L}. The width W_{151L} is greater than the width W_{151U}. However, the width W_{151L} may be the same as the width W_{151U}.

On the side surface in the Y-direction and the upper surface of the insulating layer 151, the tunnel insulating film 131, the electric charge accumulating film 132, and the block insulating film 133 of the gate insulating film 130 as described above are disposed.

As illustrated in FIG. 3 and FIG. 5, for example, the region between the plurality of insulating layers 151 includes the end portions in the X-direction of the plurality of conductive layers 110 arranged in the Z-direction. These plurality of end portions are mutually different in positions in the X-direction. Therefore, the end portions in the X-direction of the plurality of conductive layers 110 form a substantially staircase-shaped structure. Also, on the upper surfaces of the end portions in the X-direction of these plurality of conductive layers 110, an insulating layer 152 is disposed. The insulating layer 152 has an approximately staircase-shape along the above-described structure in the approximately staircase shape. The insulating layer 152 includes an insulating layer of silicon nitride (Si₃N₄) or the like.

Also, as illustrated in FIG. 3 and FIG. 5, for example, a plurality of contact electrodes CC arranged in the X-direction are disposed in the hook-up region R_{HU} of the memory block BLK. These plurality of contact electrodes CC may include, for example, a stacked film of a barrier conductive film of titanium nitride (TiN) and the like and a metallic film of tungsten (W) and the like. As illustrated in FIG. 5, for example, these plurality of contact electrodes CC each include a portion 153 in an approximately columnar shape extending in the Z-direction, and a portion 154 in a substantially disc-like shape connected to this portion 153 and any of the conductive layers 110.

The plurality of conductive layers 110 cover the outer peripheral surface of the portion 153. Also, an insulating layer 155 of tungsten oxide, silicon oxide (SiO₂) or the like is disposed between the portion 153 and the plurality of conductive layers 110.

The portion 154 is disposed along the upper surface of the corresponding conductive layer 110. The lower surface of the portion 154 is connected to the insulating layer 155 and the conductive layer 110. The outer peripheral surface of the portion 154 is connected to the insulating layer 152.

In the illustrated example, among the plurality of contact electrodes CC, the one closest to the memory cell region R_{MC} is connected to the first conductive layer 110 counted from above. Also, the one second-closest to the memory cell region R_{MC} is connected to the second conductive layer 110 counted from above. In the same manner, the one a-th closest (a is a natural number) to the memory cell region R_{MC} is connected to the a-th conductive layer 110 counted from above.

[Configuration of Inter-Block Structure SW]

As illustrated in FIG. 4, the inter-block structure SW includes a semiconductor layer 140 extending in the Z-direction and the X-direction, and a part of the tunnel insulating film 131, the electric charge accumulating film 132, and the block insulating film 133.

The semiconductor layer 140 is, for example, a part of the semiconductor substrate 100. For example, the semiconductor layer 140 is of P-type single-crystal silicon.

Also, the crystal orientation of the semiconductor layer 140 matches the crystal orientation of the other portions of the semiconductor substrate 100.

The semiconductor layer 140 extends in the Z-direction and the X-direction. The upper surface of the semiconductor layer 140 is a part of the surface 100a. The lower end of the semiconductor layer 140 is connected to the surface 100b of the semiconductor substrate 100. The length in the X-direction of the semiconductor layer 140 is approximately the same as the length in the X-direction of the memory block BLK.

The width in the Y-direction of the lower end portion of the semiconductor layer 140 may be greater than the width in the Y-direction of the upper end portion of the semiconductor layer 140. In the illustrated example, the width in the Y-direction of a portion of the semiconductor layer 140, opposed to the uppermost conductive layer 110, is denoted by width W_{140U}. The width in the Y-direction of the portion of the semiconductor layer 140, opposed to the lowermost conductive layer 110, is denoted by width W_{14oL}. The width W_{14oL} is greater than the width W_{140U}. However, the width W_{140L} may be the same as the width W_{140U}.

On the side surface in the Y-direction and the upper surface of the semiconductor layer 140, the tunnel insulating film 131, the electric charge accumulating film 132, and the block insulating film 133 of the gate insulating film 130 as described above are disposed.

[Manufacturing Method]

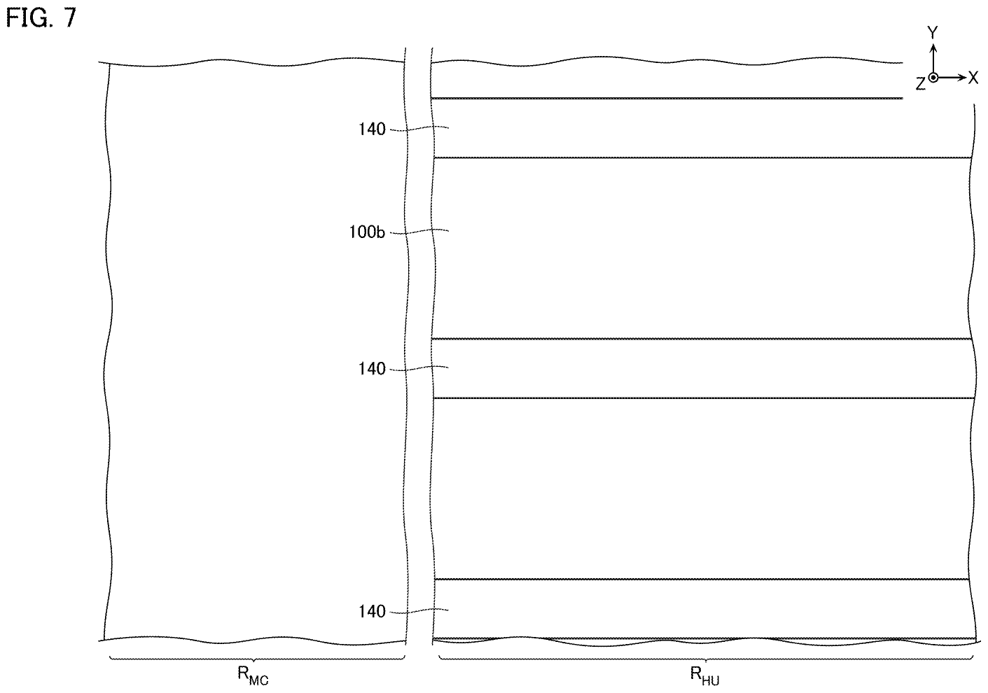

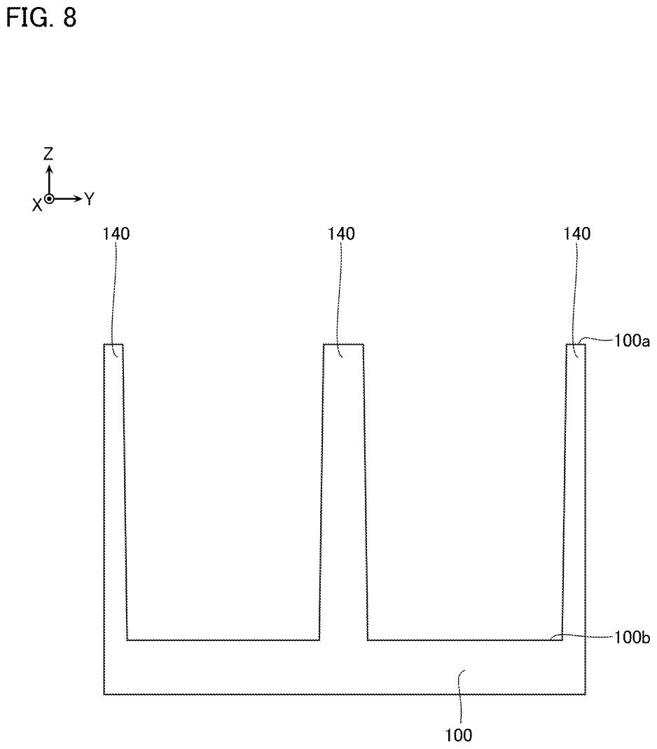

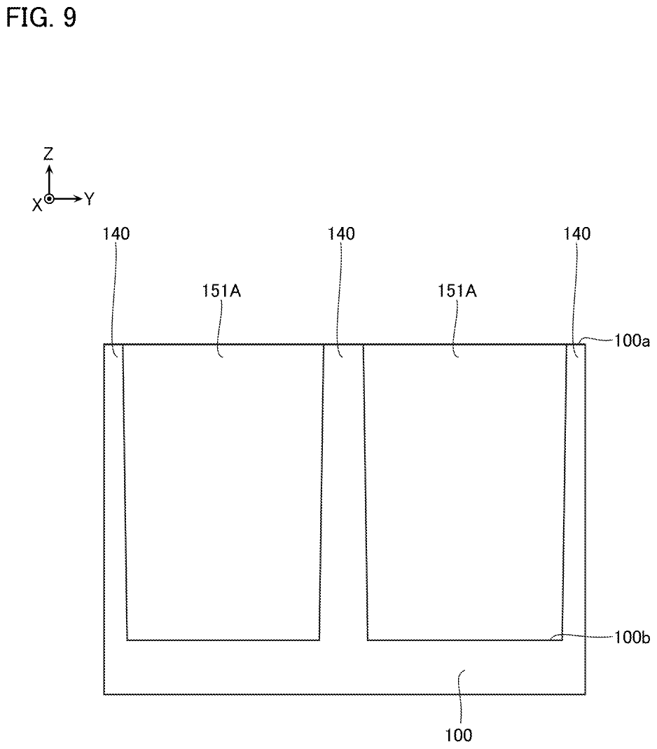

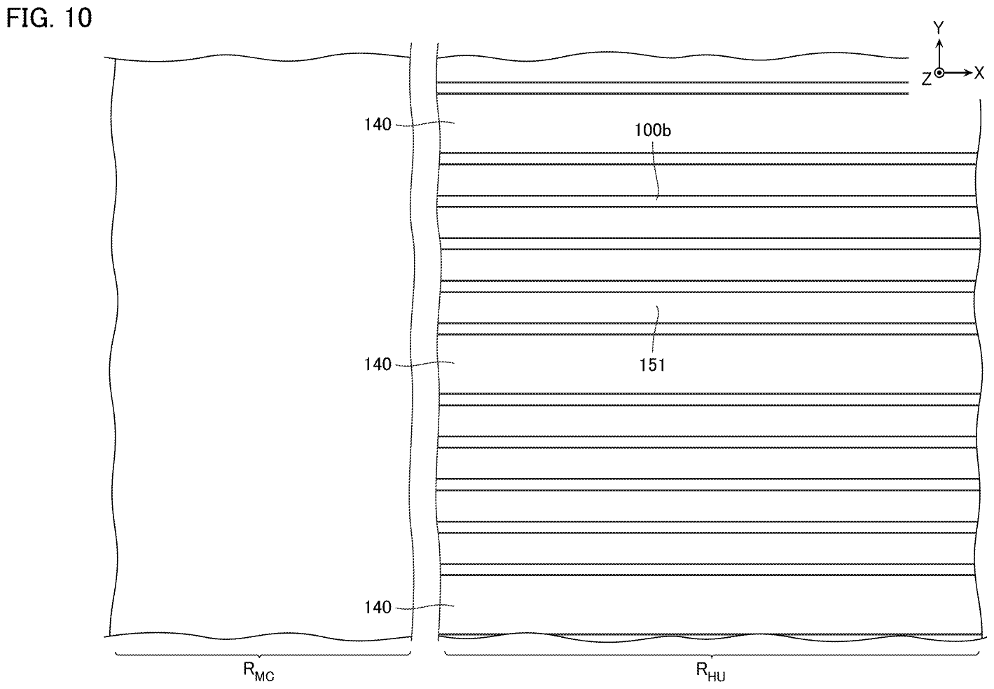

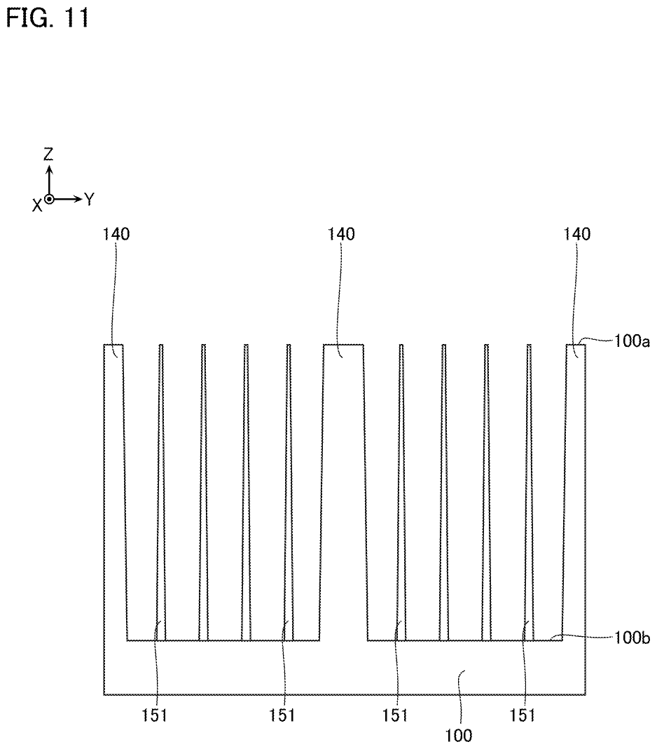

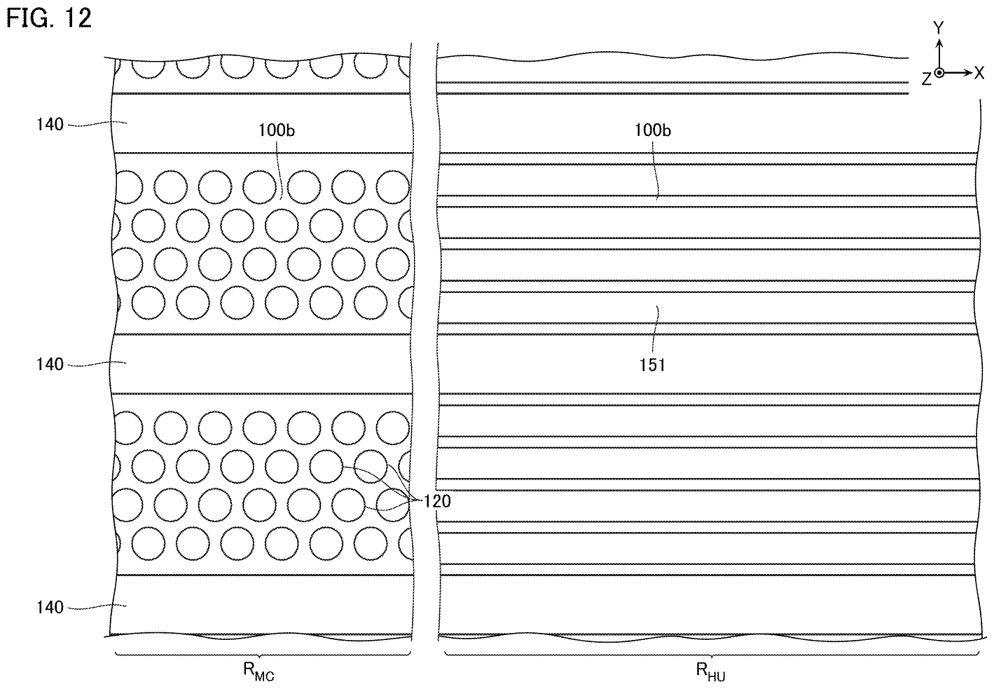

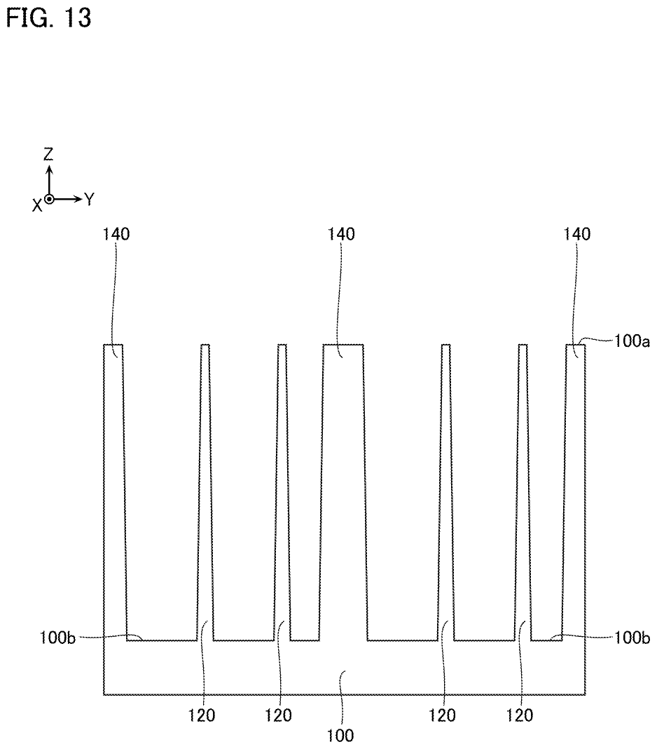

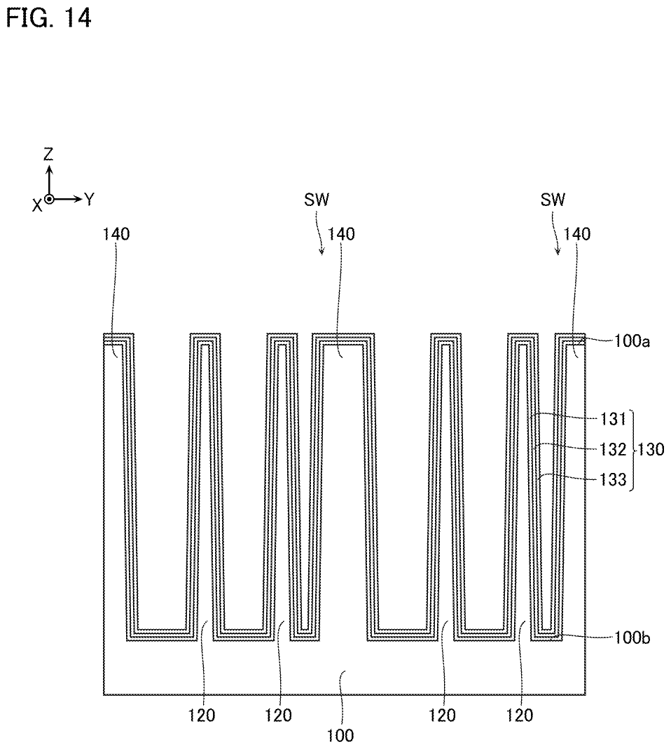

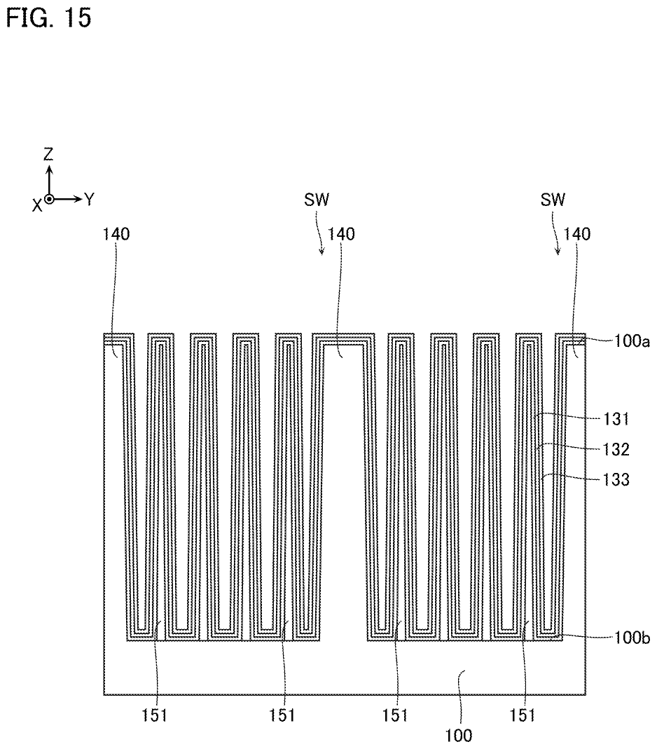

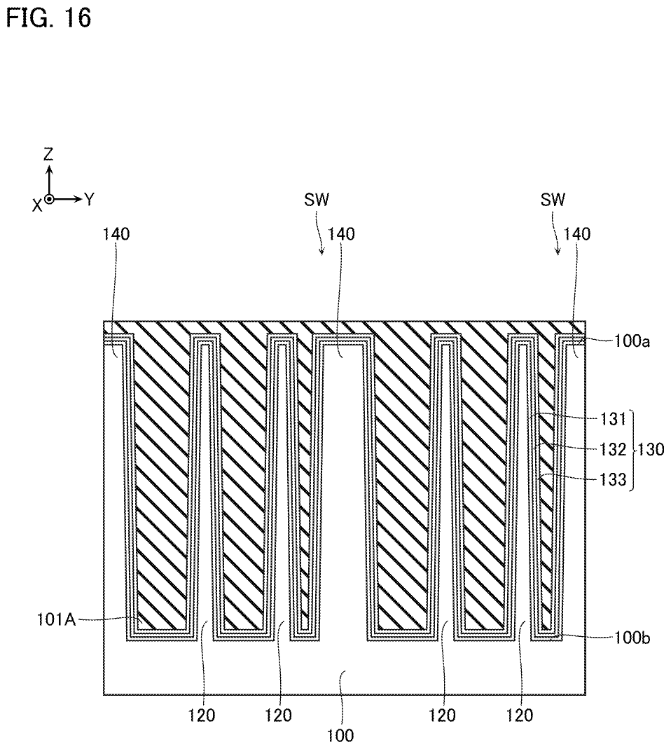

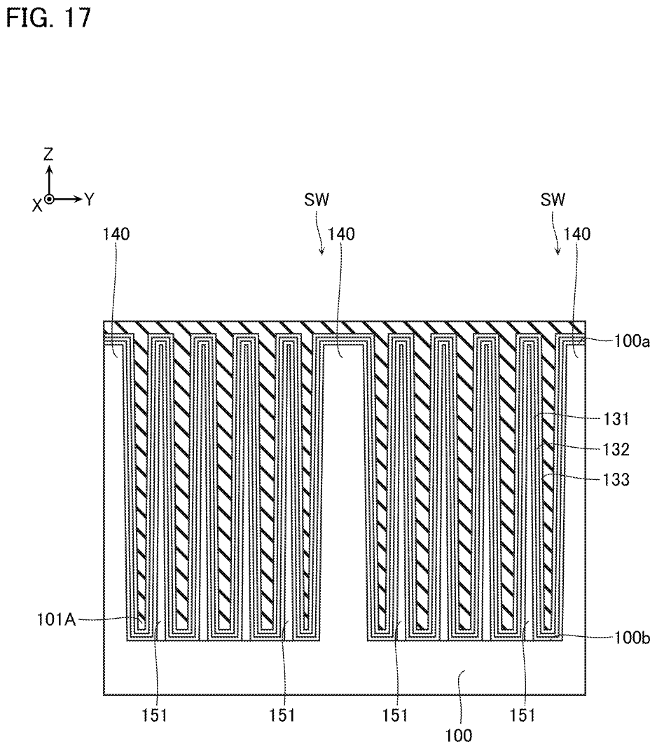

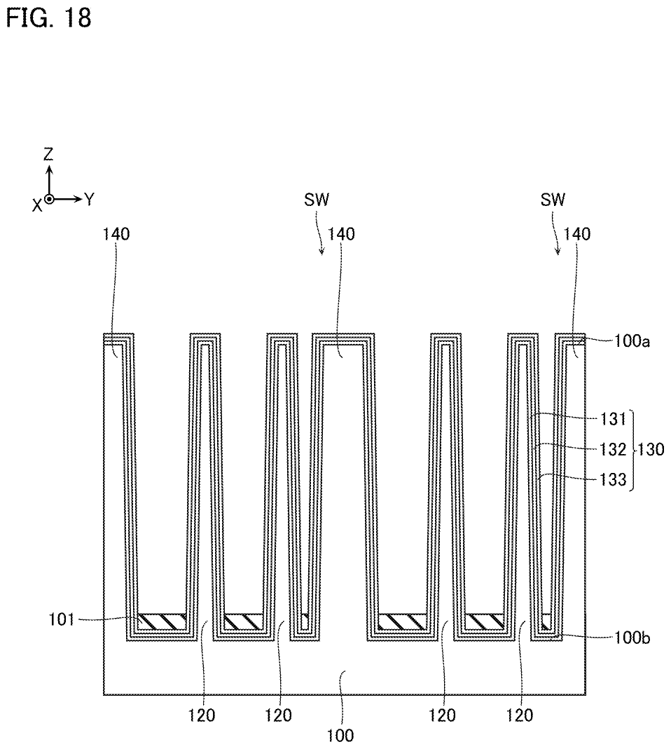

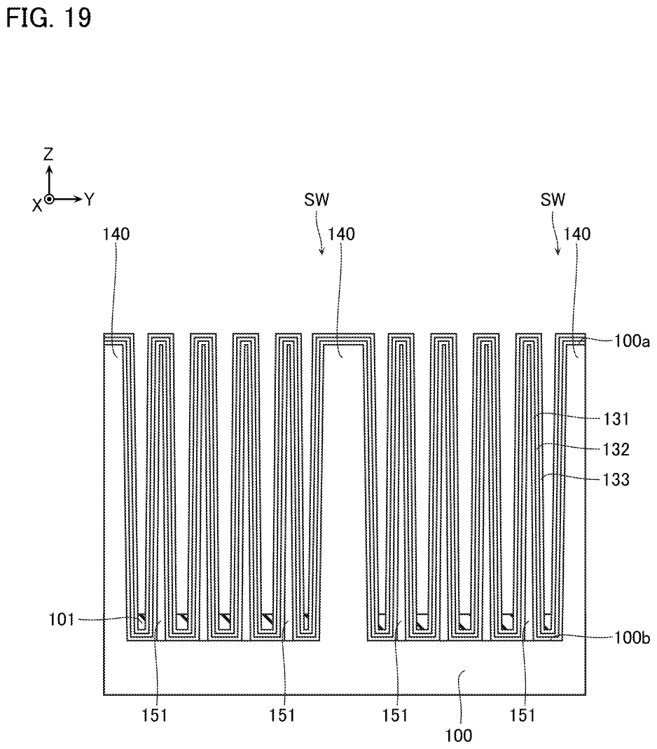

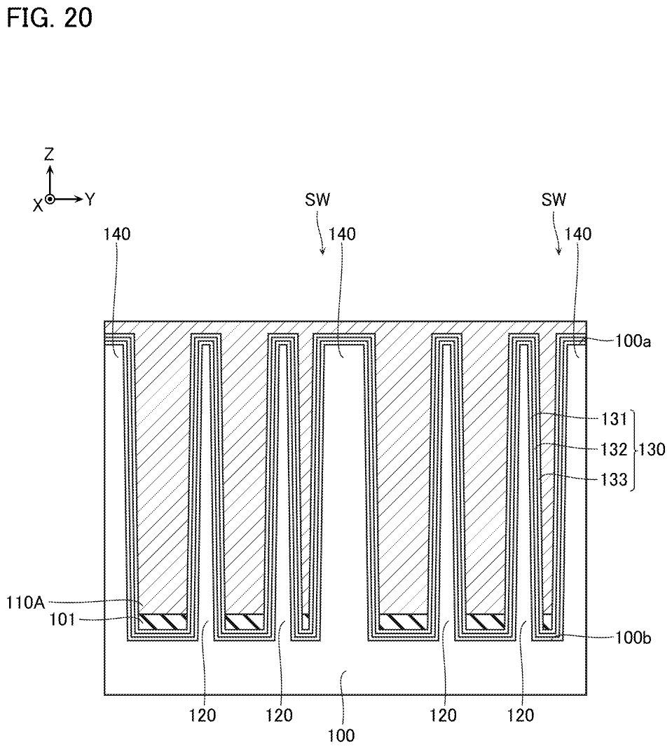

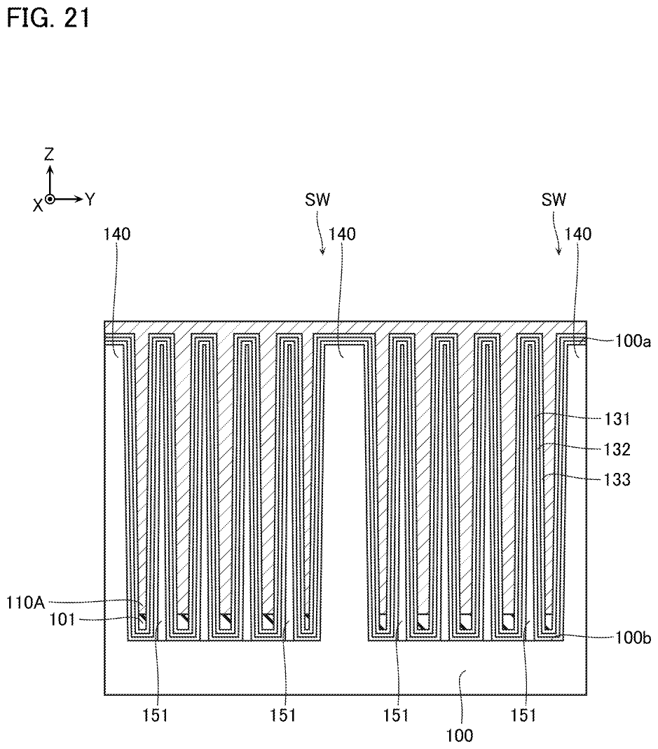

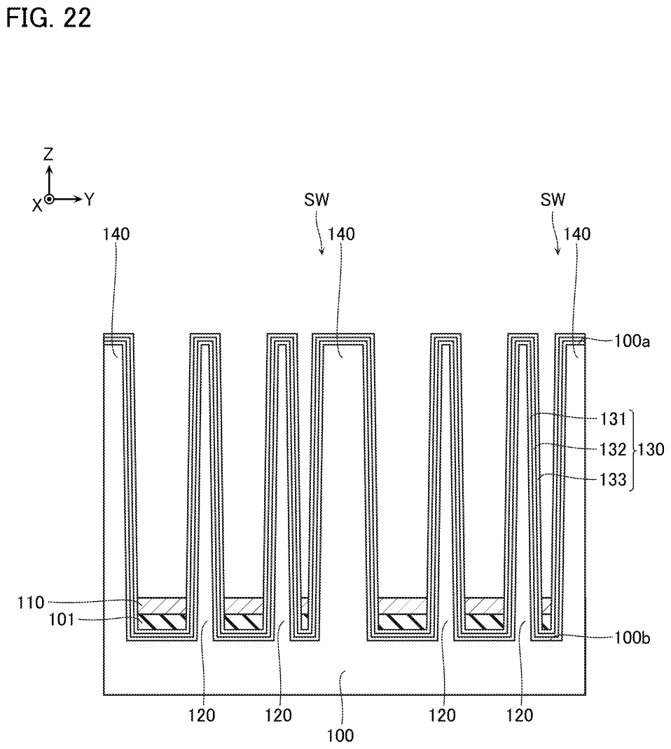

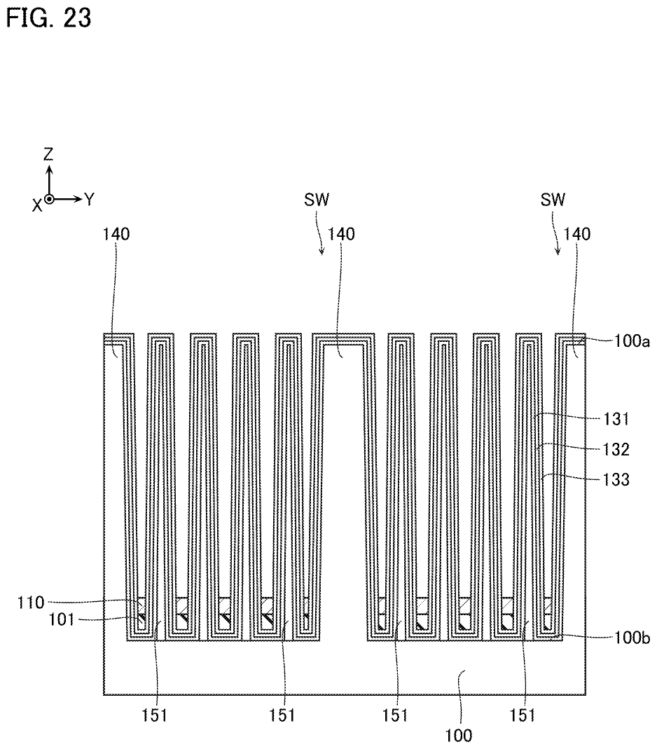

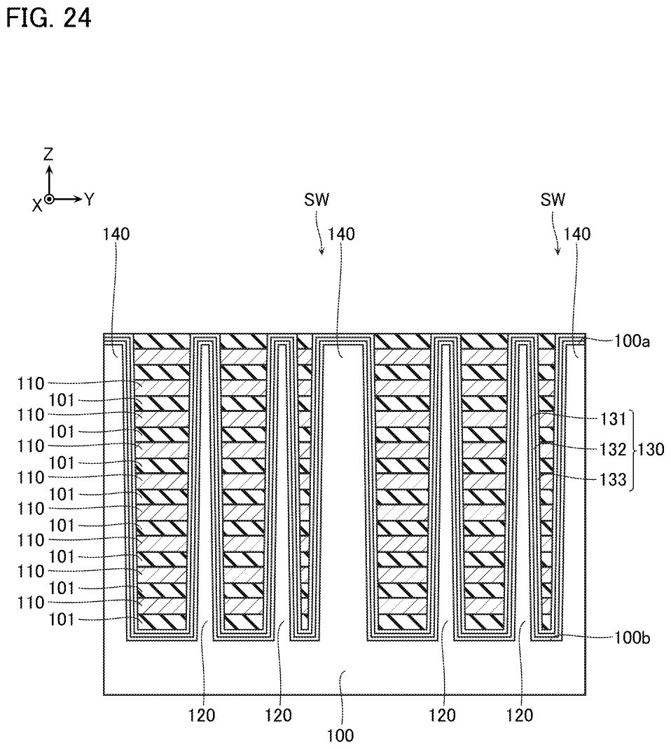

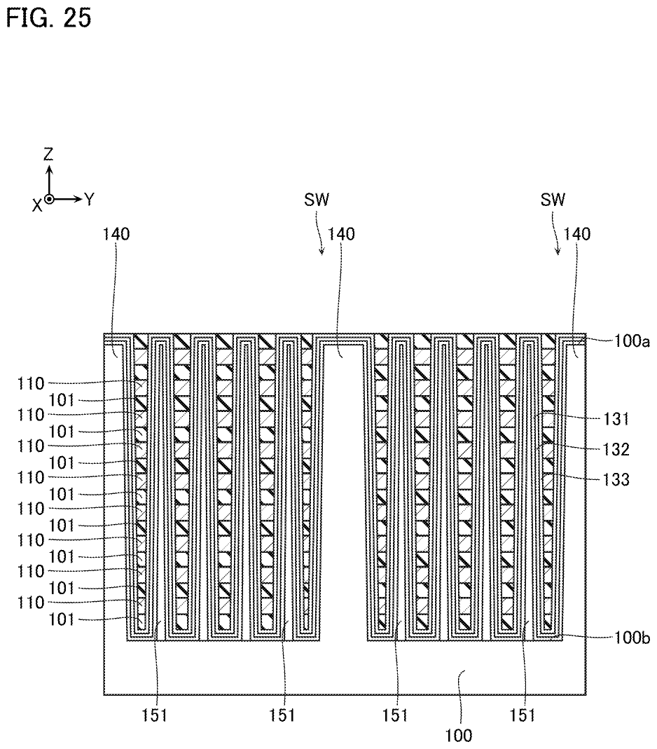

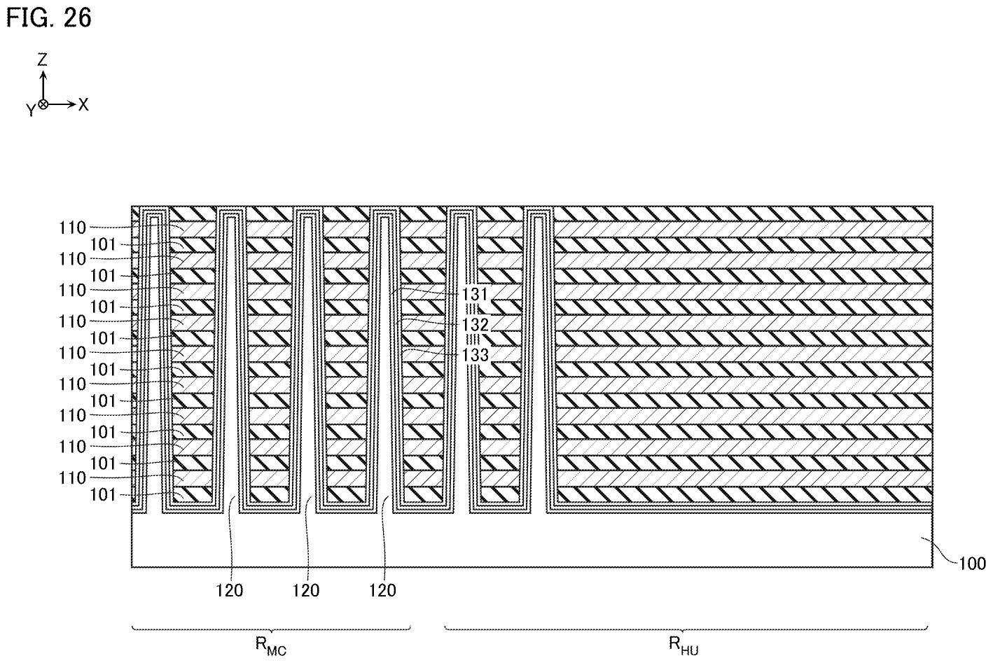

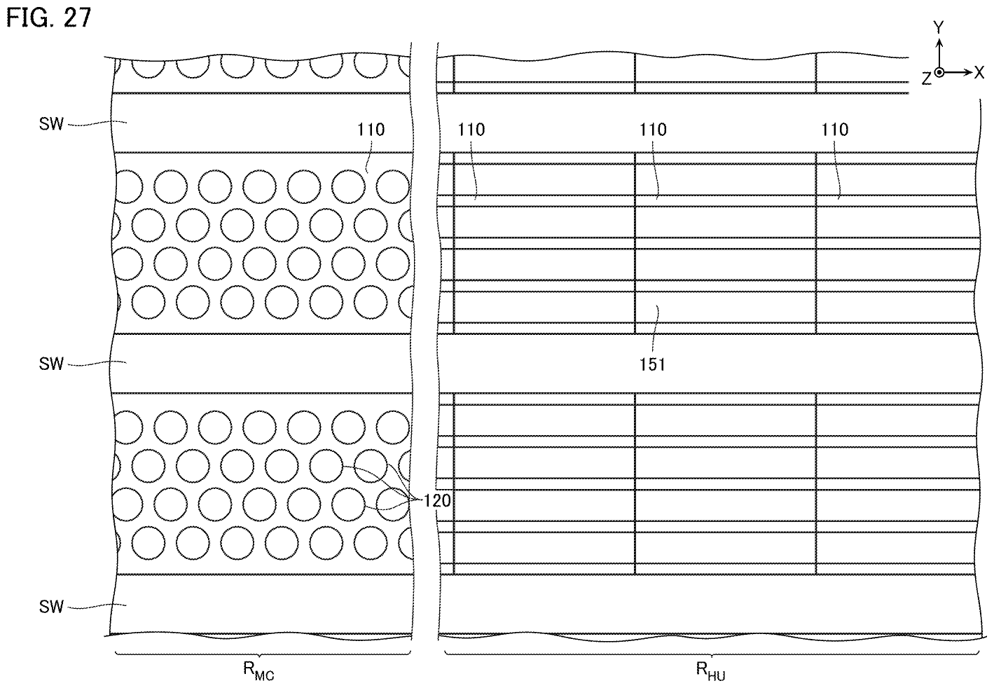

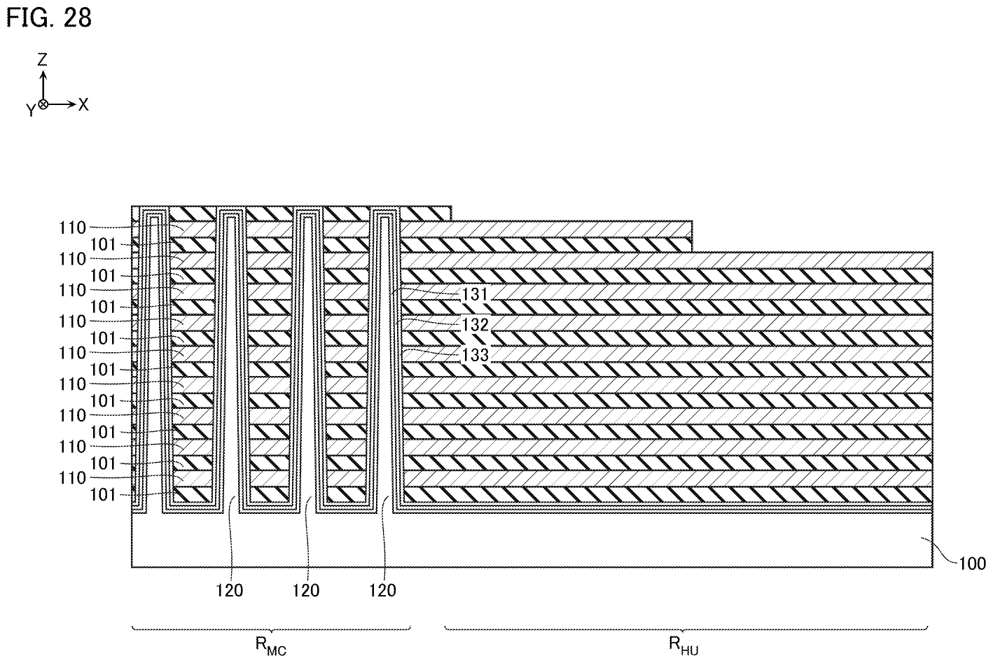

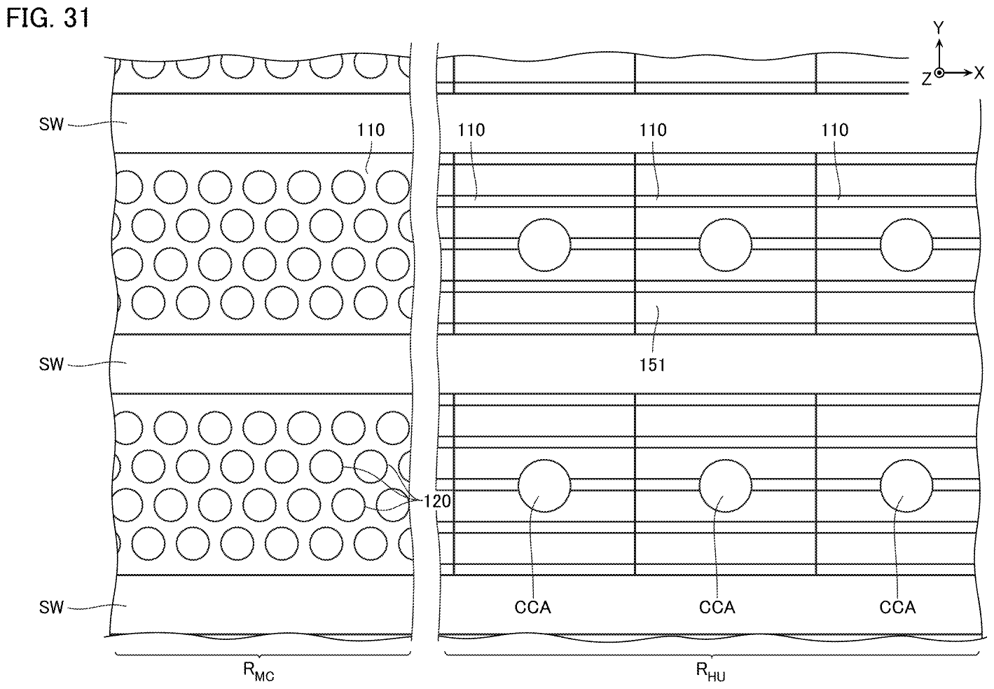

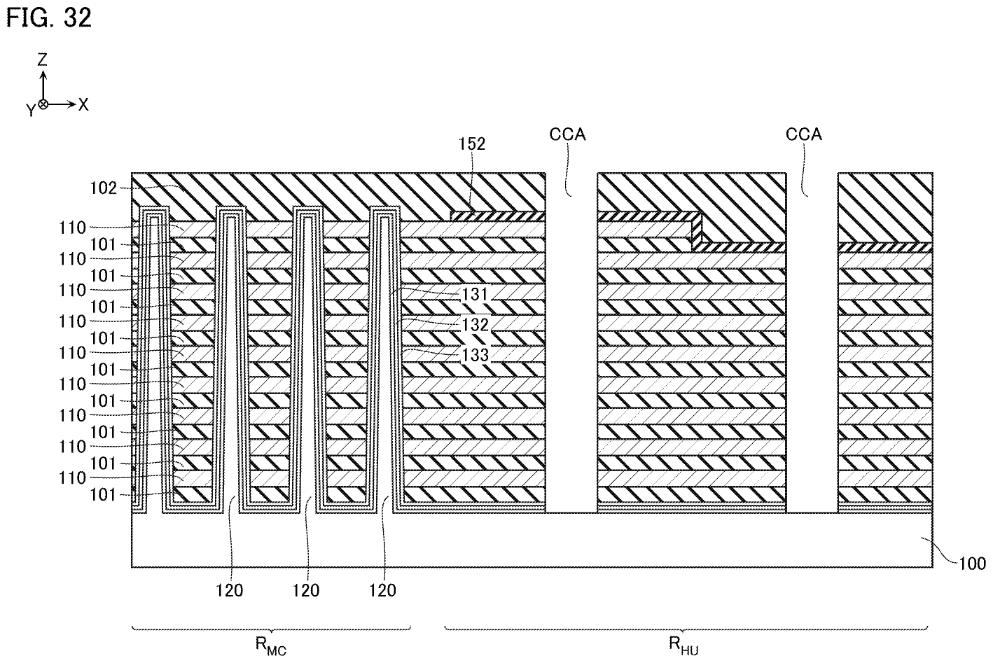

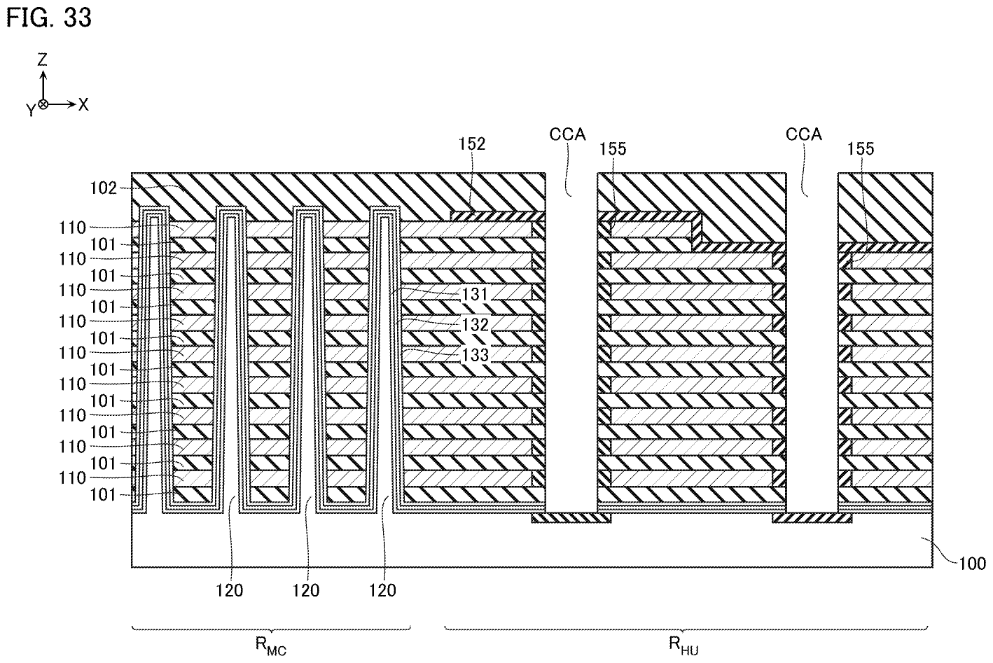

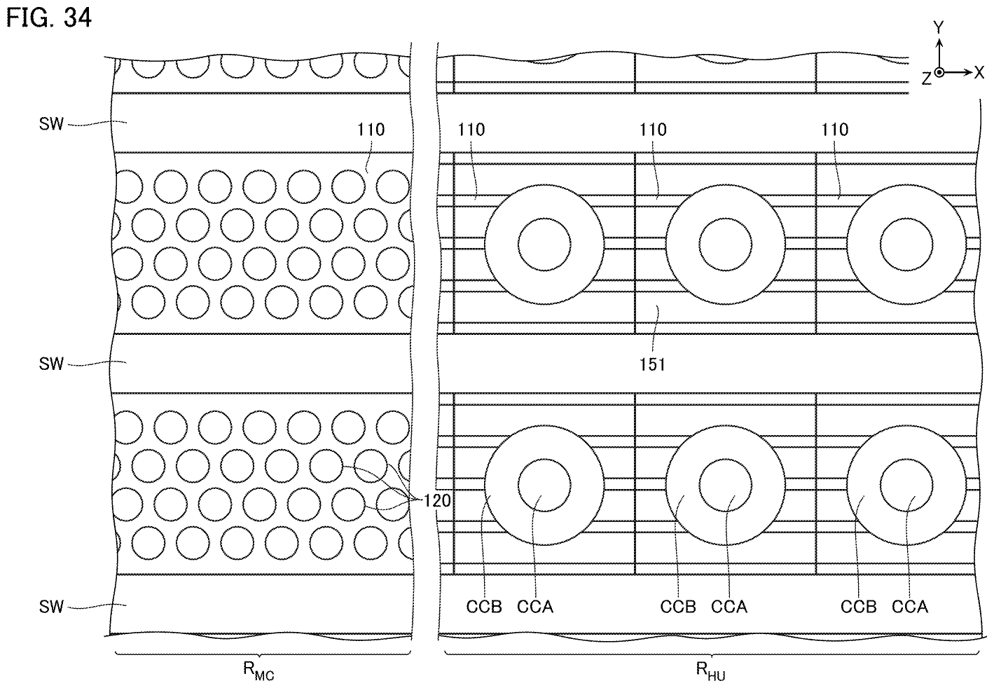

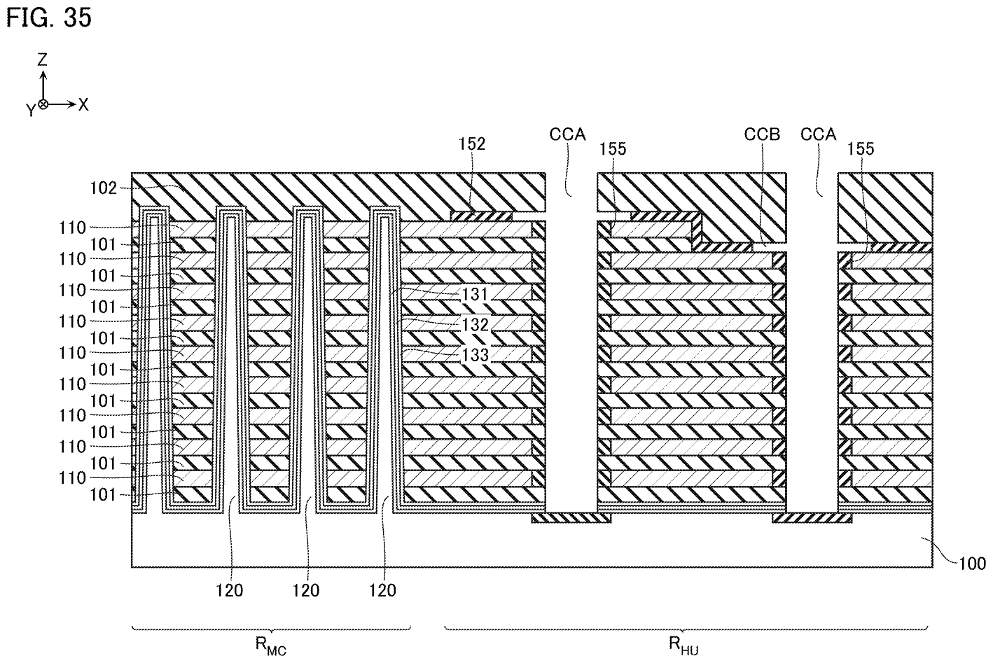

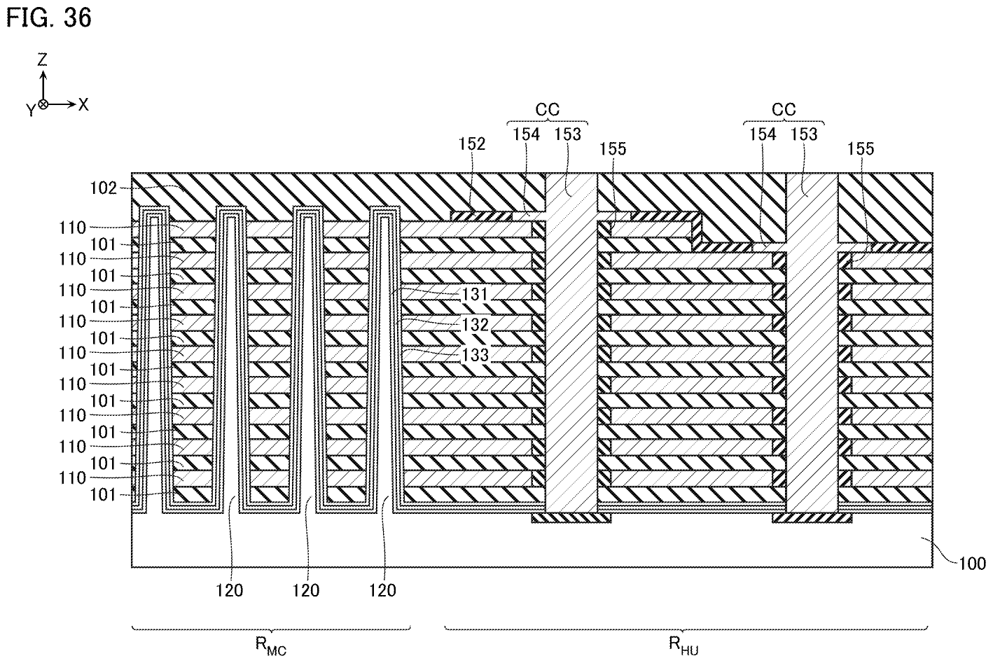

Next, with reference to FIG. 7 to FIG. 36, the manufacturing method for the semiconductor memory device according to the first embodiment will be described. FIG. 7, FIG. 10, FIG. 12, FIG. 27, FIG. 31, and FIG. 34 are schematic plan views for describing the manufacturing method, indicating the portion corresponding to FIG. 3. FIG. 8, FIG. 9, FIG. 11, FIG. 15, FIG. 17, FIG. 19, FIG. 21, FIG. 23, and FIG. 25 are schematic cross-sectional views for describing the manufacturing method, indicating the portion corresponding to FIG. 6. FIG. 13, FIG. 14, FIG. 16, FIG. 18, FIG. 20, FIG. 22, and FIG. 24 are schematic cross-sectional views for describing the manufacturing method, indicating the portion corresponding to a part of FIG. 4. FIG. 26, FIG. 28 to FIG. 30, FIG. 32, FIG. 33, FIG. 35, and FIG. 36 are schematic cross-sectional views for describing the manufacturing method, indicating the portion corresponding to FIG. 5.

For example, as illustrated in FIG. 7 and FIG. 8, in the manufacturing method, a part of the semiconductor substrate 100 is removed in the hook-up region R_{HU}. Thus, the plurality of semiconductor layers 140 and the surface 100b are formed in the hook-up region R_{HU}. This process is performed by a method, such as reactive ion etching (RIE) .

Next, as illustrated in FIG. 9, for example, an insulating layer 151A is formed in the hook-up region R_{HU}. In this process, the insulating layer of silicon oxide or the like is formed on the surface 100a and the surface 100b of the semiconductor substrate 100 by a method, such as Chemical Vapor Deposition (CVD) or the like. Also, by using the surface 100a of the semiconductor substrate 100 as a stopper, a flattening process, such as Chemical Mechanical Polishing (CMP) is performed to remove a part of the insulating layer, thereby exposing the surface 100a of the semiconductor substrate 100.

Next, as illustrated in FIG. 10 and FIG. 11, for example, the insulating layer 151A is separated in the Y-direction, thus forming the plurality of insulating layers 151. This process is performed by a method, such as RIE.

Next, as illustrated in FIG. 12 and FIG. 13, for example, a part of the semiconductor substrate 100 is removed in the memory cell region R_{MC}. Thus, in the memory cell region R_{MC}, the plurality of semiconductor layers 120, the plurality of semiconductor layers 140 and the surface 100b are formed. This process is performed by a method, such as RIE.

Next, as illustrated in FIG. 14 and FIG. 15, for example, in the memory cell region R_{MC} and the hook-up region R_{HU}, the tunnel insulating film 131, the electric charge accumulating film 132, and the block insulating film 133 are formed on the outer peripheral surfaces and upper surfaces of the plurality of semiconductor layers 120, the side surfaces in the Y-direction and upper surfaces of the plurality of semiconductor layers 140, the side surfaces in the Y-direction and upper surfaces of the plurality of insulating layers 151, and the surface 1 00b. In this process, the gate insulating film 130 is formed on the outer peripheral surface of the semiconductor layer 120. Also, the inter-block structure SW is formed. This process is performed by a method, such as CVD.

Next, as illustrated in FIG. 16 and FIG. 17, for example, in the memory cell region R_{MC} and the hook-up region R_{HU}, an insulating layer 101A is formed on positions corresponding to the outer peripheral surfaces and upper surfaces of the plurality of semiconductor layers 120, the side surfaces in the Y-direction and upper surfaces of the plurality of semiconductor layers 140, the side surfaces in the Y-direction and upper surfaces of the plurality of insulating layers 151, and the surface 100b. This process is performed by a method, such as CVD.

Next, as illustrated in FIG. 18 and FIG. 19, for example, a part of the insulating layer 101A is removed to form the insulating layer 101. This process is performed by a method, such as RIE. Also, in this process, the thickness in the Z-direction of the insulating layer 101 is controlled to a certain size or less. Also, this process is performed in a condition where the block insulating film 133 is not removed.

Next, for example, as illustrated in FIG. 20 and FIG. 21, in the memory cell region R_{MC} and the hook-up region R_{HU}, a conductive layer 110A is formed at positions corresponding to the outer peripheral surfaces and upper surfaces of the plurality of semiconductor layers 120, the side surfaces in the Y-direction and upper surfaces of the plurality of semiconductor layers 140, and the side surfaces in the Y-direction and upper surfaces of the plurality of insulating layers 151. This process is performed by a method, such as CVD.

Next, as illustrated in FIG. 22 and FIG. 23, for example, a part of the conductive layer 110A is removed to form the conductive layer 110. This process is performed by a method, such as RIE. Also, in this process, the thickness in the Z-direction of the conductive layer 110 is controlled to a certain size or less. Also, this process is performed in the condition where the block insulating film 133 is not removed.

Next, as illustrated in FIG. 24 to FIG. 26, for example, the plurality of conductive layers 110 and the plurality of insulating layers 101 are formed. In this process, the processes described with reference to, for example, FIG. 16 to FIG. 23 are repeatedly performed.

Next, as illustrated in FIG. 27 and FIG. 28, for example, the plurality of conductive layers 110 and the plurality of insulating layers 101 are partially removed to form a staircase-shaped structure in the hook-up region R_{HU}. In this process, a resist is formed on the upper surface of the structure described with reference to, for example, FIG. 24 to FIG. 26. Next, a part of the resist is removed to expose a part of the conductive layer 110. Next, the portion exposed from the resist of the conductive layer 110 is selectively removed to expose a part of the insulating layer 101. Next, the portion exposed from the resist of the insulating layer 101 is selectively removed to expose a part of the conductive layer 110. In the same manner, the process to remove a part of the resist, the process to remove a part of the conductive layer 110, and the process to remove a part of the insulating layer 101 are repeatedly performed. Thus, all of the conductive layers 110 arranged in the Z-direction are partially exposed.

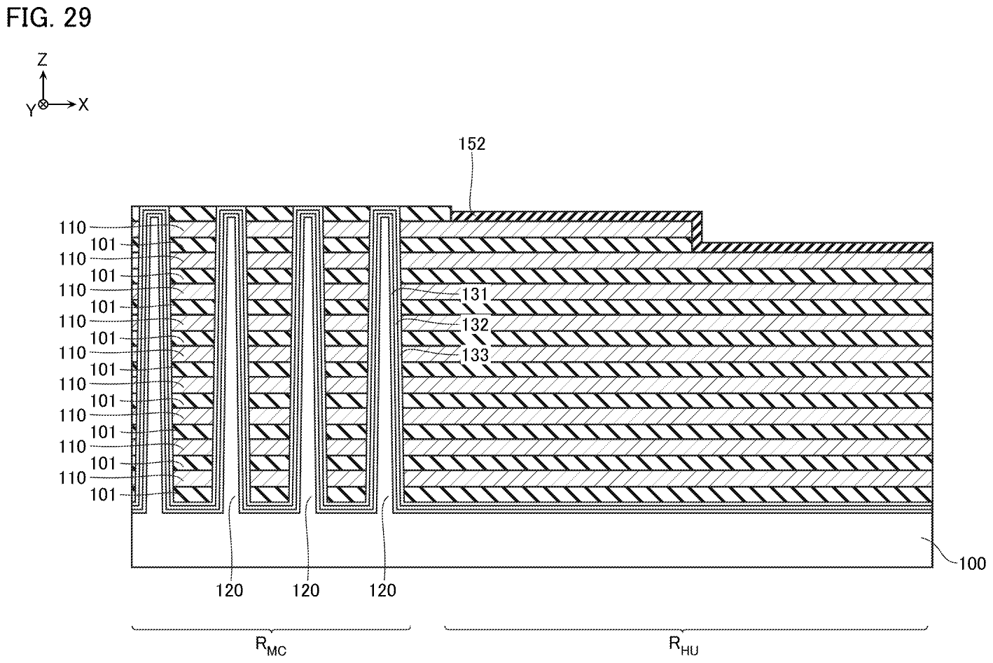

Next, as illustrated in FIG. 29, for example, in the hook-up region R_{HU}, the insulating layer 152 covering the staircase-shaped structure as described above is formed. This process is performed by a method, such as CVD.

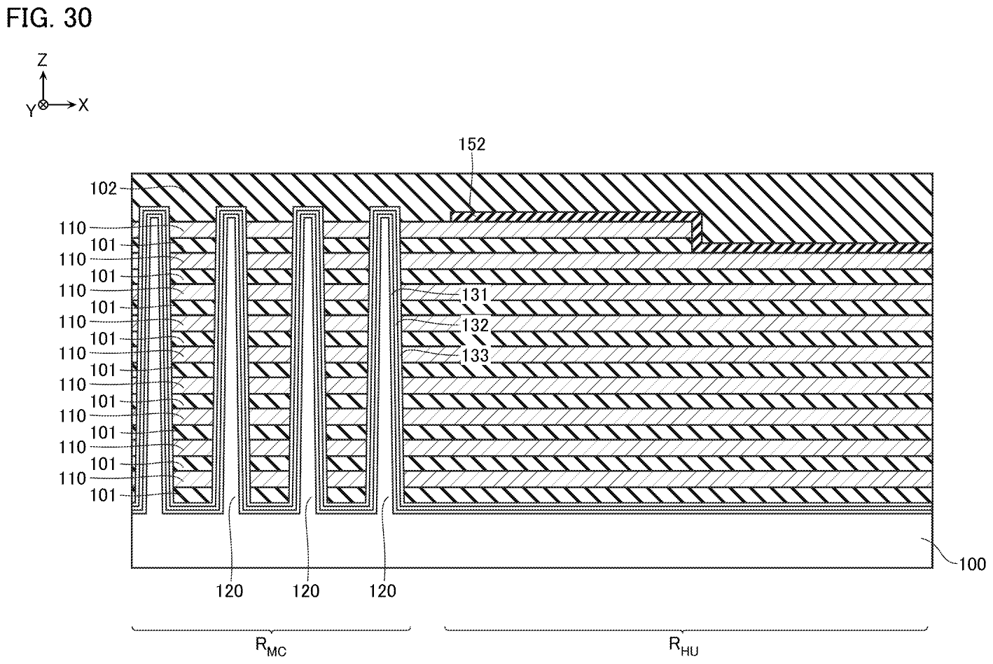

Next, as illustrated in FIG. 30, for example, on the upper surface of the structure described with reference to FIG. 29, an insulating layer 102 of silicon oxide (SiO₂) or the like is formed. This process is performed by a method, such as CVD.

Next, as illustrated in FIG. 31 and FIG. 32, for example, contact holes CCA are formed at positions corresponding to the contact electrodes CC. The contact hole CCA is a through-hole penetrating the insulating layer 102 and the insulating layer 152, and extending in the Z-direction. In the illustrated example, the contact hole CCA penetrates all the plurality of conductive layers 110 and all the plurality of insulating layers 101 arranged in the Z-direction. In addition, from the bottom surface of the contact hole CCA, a part of the semiconductor substrate 100 is exposed.

Next, as illustrated in FIG. 33, for example, the insulating layer 155 is formed. This process may be performed by oxidized treatment, for example. Also, this process may also be performed by selectively removing a part of the conductive layer 110 by a method of wet etching or the like and forming the insulating layer 155.

Next, as illustrated in FIG. 34 and FIG. 35, for example, a part of the insulating layer 152 is selectively removed to form a cavity CCB. The cavity CCB exposes the upper surface of the conductive layer 110 and communicates with the contact hole CCA. This process is performed by a method, such as wet etching.

Next, as illustrated in FIG. 36, for example, the contact electrode CC is formed. This process is performed by a method, such as CVD. In this process, the portion 153 is formed in an approximately columnar shape on the contact hole CCA and the portion 154 is formed in an approximately disc-like shape on the cavity CCB.

[Effects]

There has been known a semiconductor memory device that includes the plurality of conductive layers arranged in the Z-direction, the plurality of semiconductor layers extending in the Z-direction and being opposed to these plurality of semiconductor layers, the plurality of electric charge accumulating portions disposed between the plurality of conductive layers and the plurality of semiconductor layers. In manufacturing such a semiconductor memory device, for example, a plurality of conductive layers are formed, and then, a memory hole penetrating the plurality of conductive layers are formed, and an electric charge accumulating layer and a semiconductor layer of polycrystalline silicon or the like are formed inside this memory hole in some cases.

In such a configuration, as the channel region of the memory transistor (memory cell) is of polycrystalline silicon, it is difficult to increase an electron mobility in the channel region in some cases. Also, as compared with a case where the channel region of the memory transistor (memory cell) is of single-crystal silicon, for example, favorable characteristics are not obtained in a write operation and a read operation in some cases.

Also, in performing high integration of such a configuration, the number of conductive layers arranged in the

Z-direction is increased in some cases. However, in this case, an aspect ratio of the memory hole tends to increase, thereby making it increasingly difficult to form memory holes.

Here, in the semiconductor memory device according to the first embodiment, as described with reference to FIG. 4 and the like, for example, the plurality of semiconductor layers 120 opposed to the plurality of conductive layers 110 are made out of a part of the semiconductor substrate 100. That is, the channel region of the semiconductor layer 120 is of single-crystal silicon. Thus, the electron mobility in the channel region can be increased. Also, as compared with the case where the channel region of the memory transistor (memory cell) is of polycrystalline silicon, for example, favorable characteristics are obtained in the write operation and read operation in some cases.

Also, in the manufacturing method according to this embodiment, instead of forming memory holes in the plurality of conductive layers or the like, as described with reference to FIG. 12 and FIG. 13, for example, the semiconductor layer 120 is formed by removing a part of the semiconductor substrate 100. Here, in some cases, it is easier to form a semiconductor layer 120 having a relatively large aspect ratio than to form a memory hole having a relatively high aspect ratio. Therefore, this method or the like allows high integration in the X-direction and the Y-direction of the semiconductor layer 120, thereby realizing high integration of the semiconductor memory device relatively easily in some cases.

Also, in this embodiment, as described with reference to FIG. 9 to FIG. 11, for example, the plurality of insulating layers 151 are formed in the hook-up region R_{HU}. Also, as described with reference to FIG. 3 and the like, the distance D₁₅₁ between two insulating layers 151 may be approximately the same as the distance D₁₂₀ between two semiconductor layers 120.

According to this method or the like, in the process described with reference to FIG. 16 and FIG. 17, for example, the height positions of the upper surface of the insulating layer 101A can be aligned to be approximately the same between the memory cell region R_{MC} and the hook-up region R_{HU}. Therefore, in the process described with the reference to FIG. 18 and FIG. 19, the thickness in the Z-direction of the insulating layer 101 can be adjusted to be approximately the same between the memory cell region R_{MC} and the hook-up region R_{HU}. The same applies to the thickness in the Z-direction of the conductive layer 110. According to this method or the like, as compared with the case where the flattening process is performed every time the insulating layer 101A, the conductive layer 110A, and the like are formed, for example, the manufacturing process can be substantially reduced.

[Second Embodiment]

[Configuration]

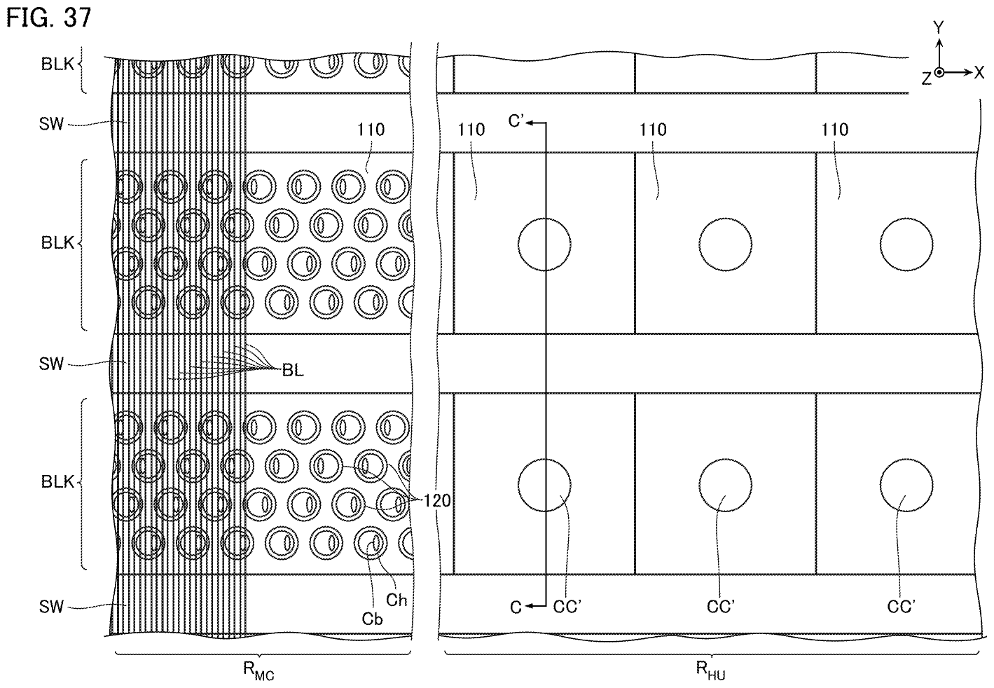

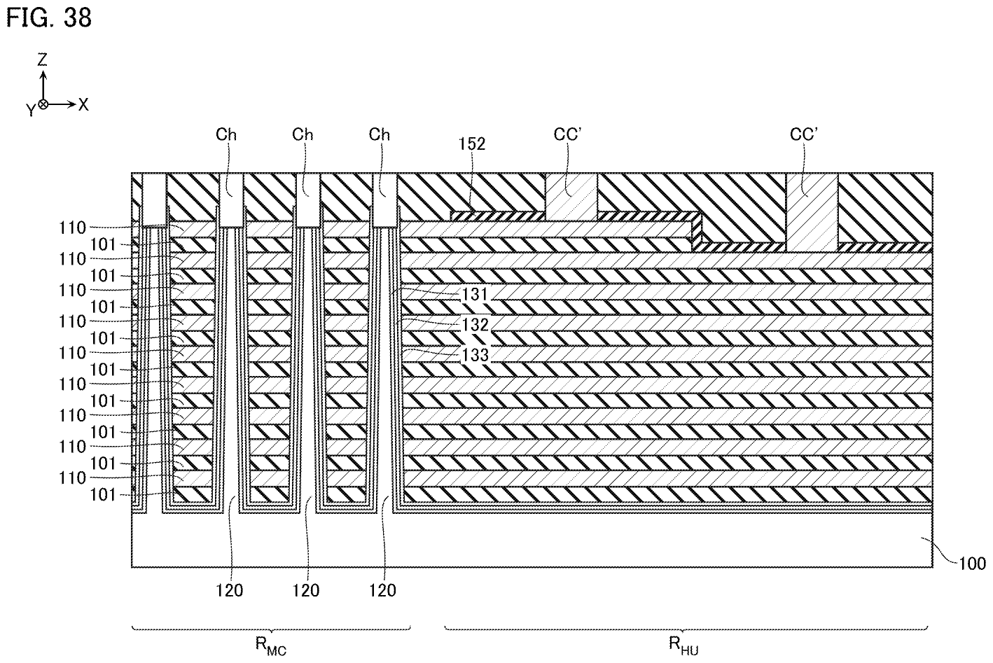

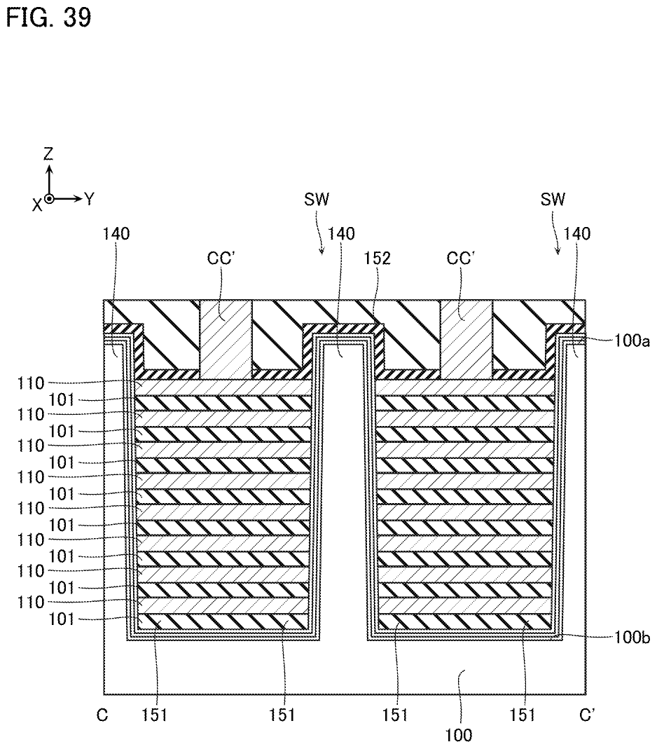

Next, with reference to FIG. 37 to FIG. 39, the configuration of the semiconductor memory device according to the second embodiment will be described. FIG. 37 is a schematic plan view illustrating the configuration of a part of the semiconductor memory device according to the second embodiment. FIG. 38 is a schematic cross-sectional view illustrating the configuration of the semiconductor memory device. FIG. 39 is a schematic cross-sectional view of the configuration as shown in FIG. 37 taking along the line C-C′ and viewed along the arrow-direction.

The semiconductor memory device according to the second embodiment is basically configured similarly to the semiconductor memory device according to the first embodiment.

However, as illustrated in FIG. 37, for example, in the hook-up region R_{HU} of the semiconductor memory device according to the second embodiment, the insulating layer 151 is not disposed. Also, the plurality of conductive layers 110 are not separated into a plurality of portions.

Also, as illustrated in FIG. 38, for example, in the hook-up region R_{HU} of the semiconductor memory device according to the second embodiment, the insulating layer 155 and the contact electrode CC are not disposed. Instead, in the hook-up region R_{HU} of the semiconductor memory device according to the second embodiment, a plurality of contact electrodes CC′ are disposed. These plurality of contact electrodes CC′ may include, for example, a stacked film of the barrier conductive films of titanium nitride (TiN) and the like and the metal films of tungsten (W) and the like. As illustrated in FIG. 38 and FIG. 39, for example, these plurality of contact electrodes CC′ each have an approximately columnar shape extending in the Z-direction, which are connected to the upper surface of any of the conductive layers 110 at the lower end.

[Manufacturing Method]

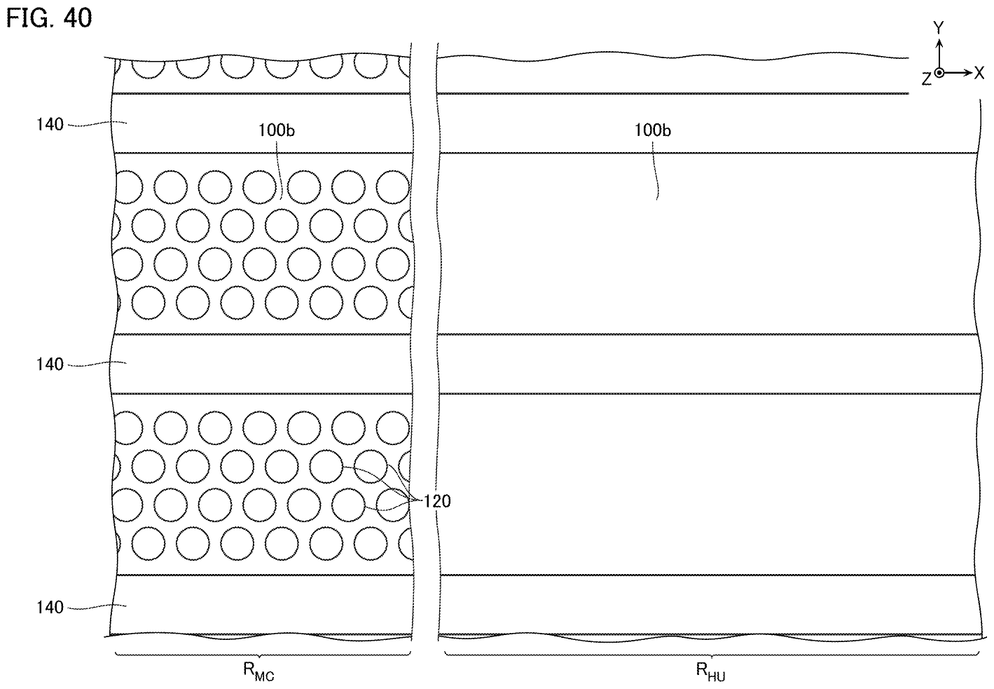

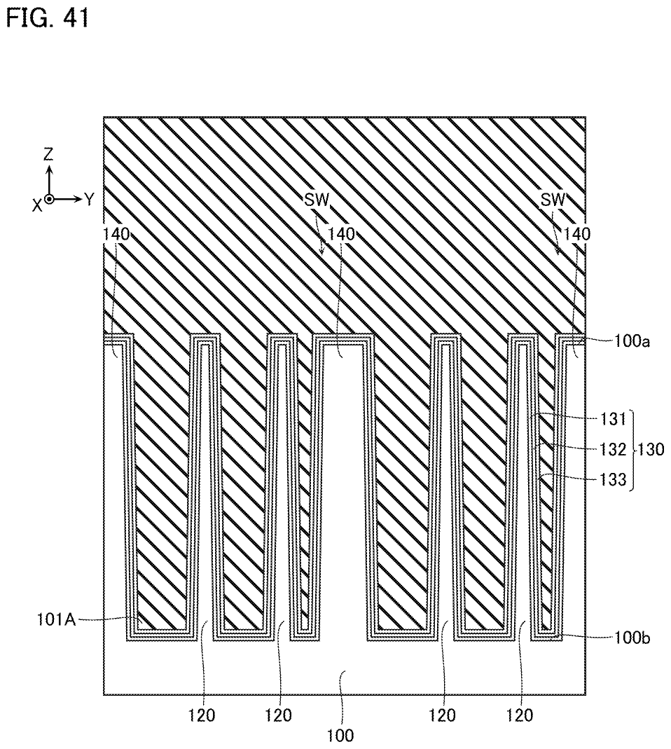

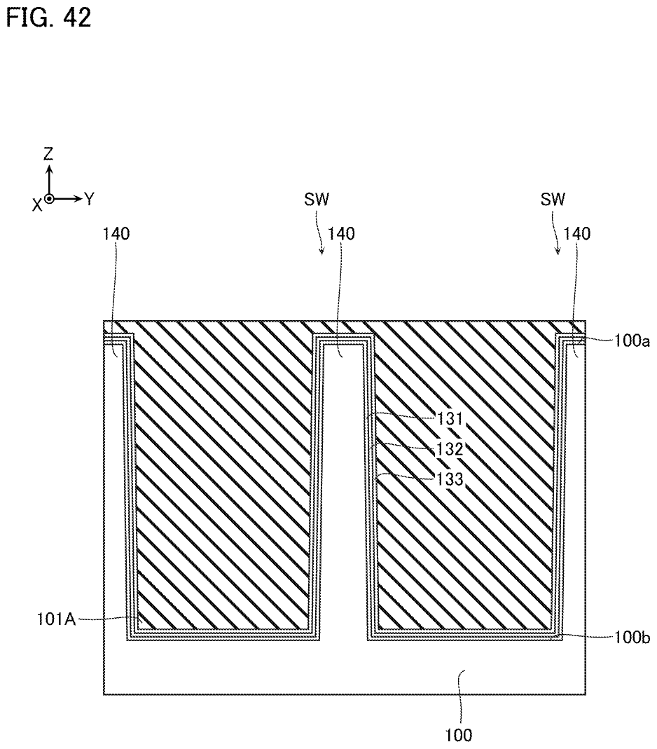

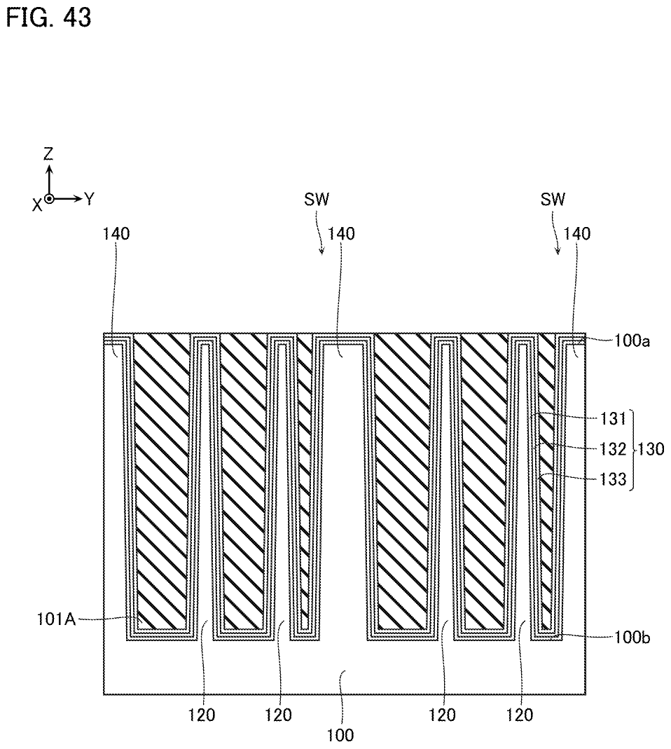

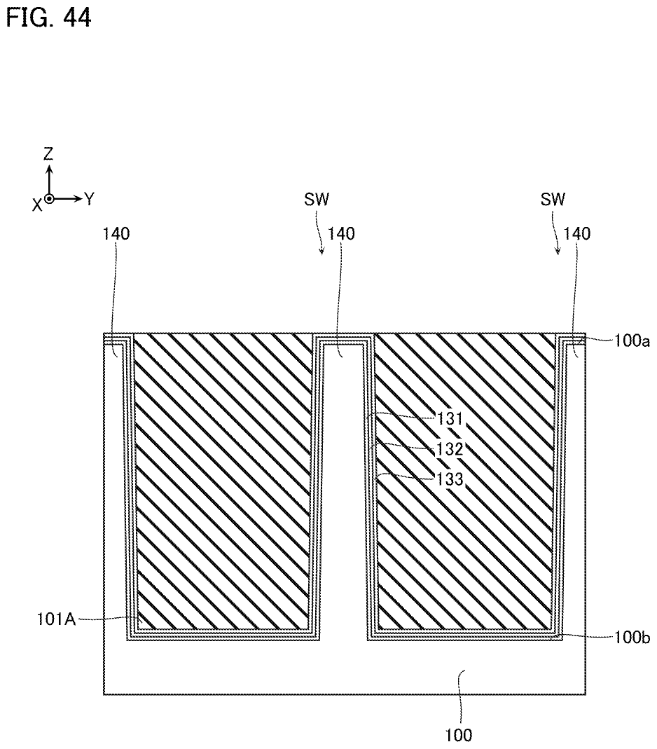

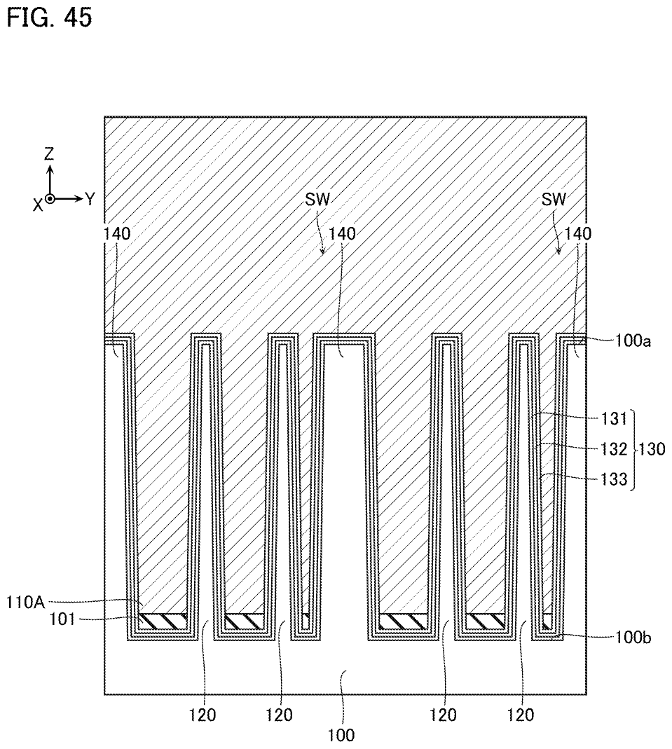

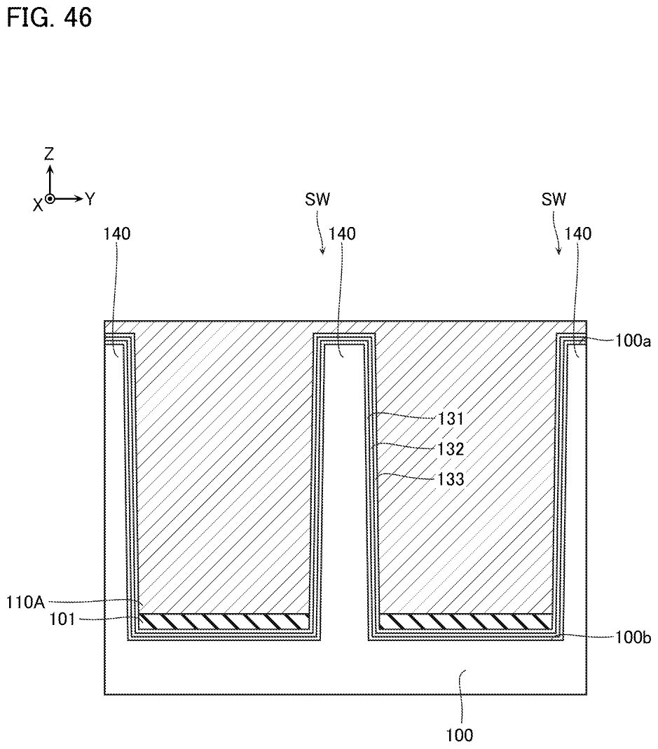

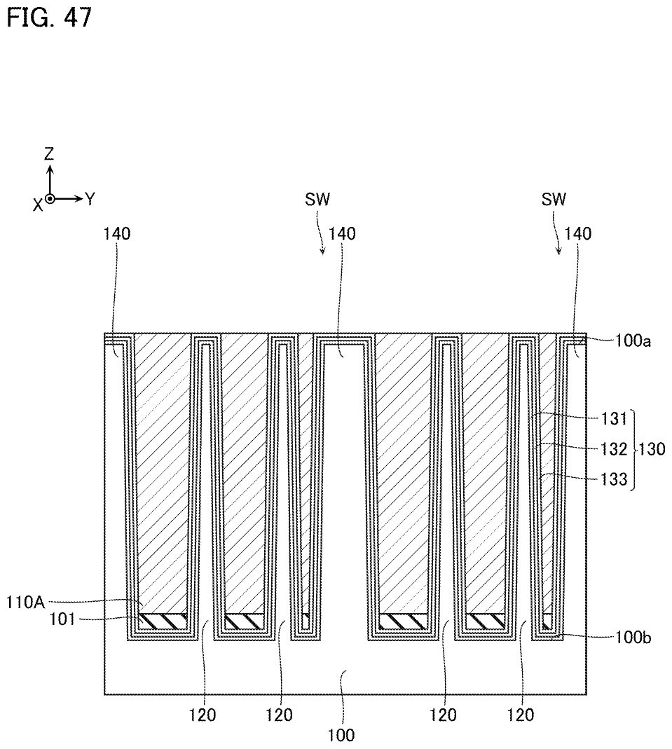

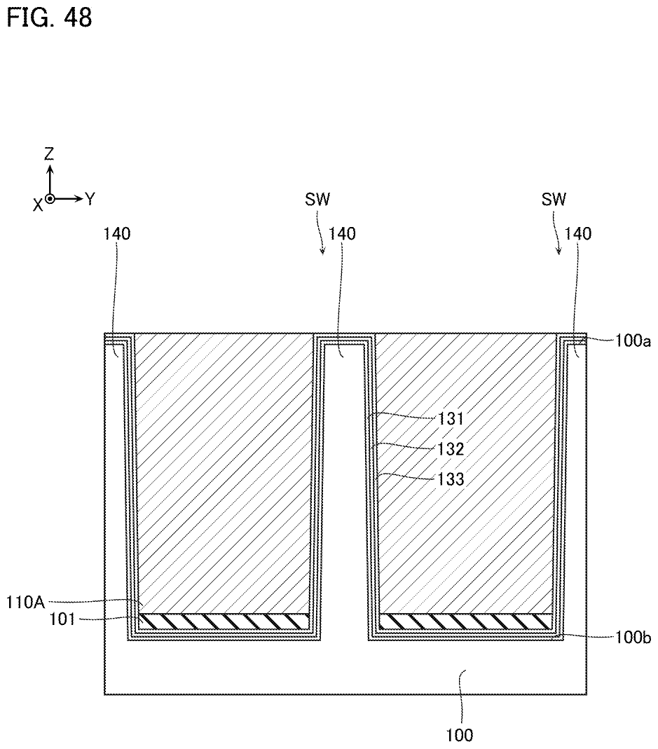

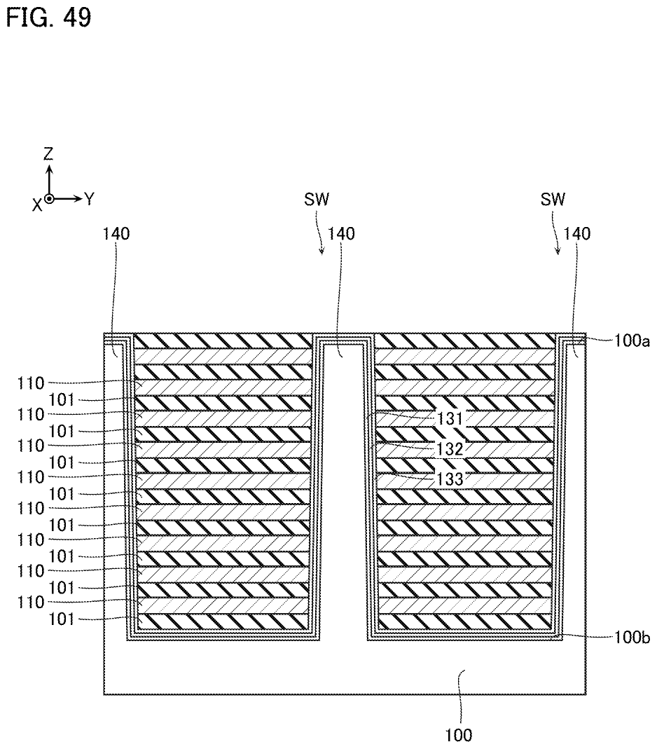

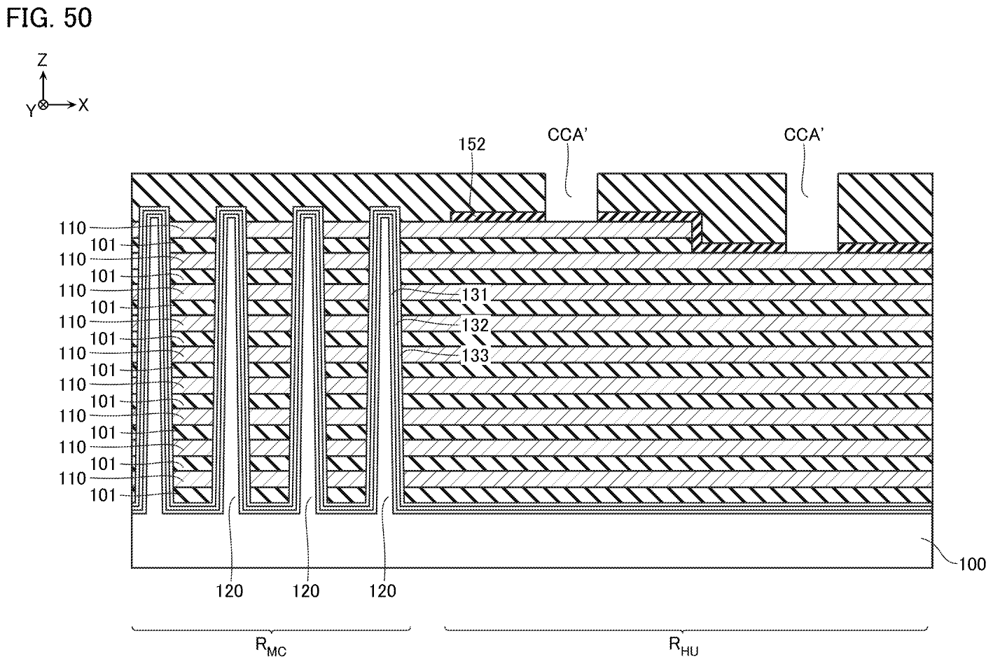

Next, with reference to FIG. 40 to FIG. 50, the manufacturing method for the semiconductor memory device according to the second embodiment will be described. FIG. 40 is a schematic plan view for describing the manufacturing method, indicating the portion corresponding to FIG. 37. FIG. 41, FIG. 43, FIG. 45, and FIG. 47 are schematic cross-sectional views for describing the manufacturing method, indicating the portion corresponding to a part of FIG. 4. FIG. 42, FIG. 44, FIG. 46, FIG. 48, and FIG. 49 are schematic cross-sectional views for describing the manufacturing method, indicating the portion corresponding to FIG. 39. FIG. 50 is a schematic cross-sectional view for describing the manufacturing method, indicating the portion corresponding to FIG. 38.

According to the manufacturing method, as illustrated in FIG. 40, for example, apart of the semiconductor substrate 100 is removed in the memory cell region R_{MC}and the hook-up region

R_{HU} to form the plurality of semiconductor layers 120, the plurality of semiconductor layers 140, and the surface 100b in the memory cell region R_{MC} and the hook-up region R_{HU}. This process is performed by a method, such as RIE. Next, the process described with reference to FIG. 14 and

FIG. 15, for example, is performed. Thus, on the outer peripheral surfaces and upper surfaces of the plurality of semiconductor layers 120, the side surfaces in the Y-direction and upper surfaces of the plurality of semiconductor layers 140, and the surface 100b in the memory cell region R_{MC} and the hook-up region R_{HU}, the tunnel insulating film 131, the electric charge accumulating film 132, and the block insulating film 133 are formed.

Next, as illustrated in FIG. 41 and FIG. 42, for example, in the memory cell region R_{MC} and the hook-up region R_{HU}, the insulating layer 101A is formed at positions corresponding to the outer peripheral surfaces and upper surfaces of the plurality of semiconductor layers 120, the side surfaces in the Y-direction and upper surfaces of the plurality of semiconductor layers 140, and the surface 100b. This process is performed by a method, such as CVD.

Next, as illustrated in FIG. 43 and FIG. 44, for example, a part of the insulating layer 101A is removed to expose the upper surface of the inter-block structure SW. In this process, the flattening process, such as CMP is performed, using the block insulating film 133 or the like as a stopper.

Next, the process described with reference to FIG. 18 and FIG. 19, for example, is performed. Thus, the insulating layer 101 is formed.

Next, as illustrated in FIG. 45 and FIG. 46, for example, in the memory cell region R_{MC} and the hook-up region R_{HU}, the conductive layer 110A is formed at positions corresponding to the outer peripheral surfaces and upper surfaces of the plurality of semiconductor layers 120, the side surfaces in the Y-direction and upper surfaces of the plurality of semiconductor layers 140, and the surface 100b. This process is performed by a method, such as CVD.

Next, as illustrated in FIG. 47 and FIG. 48, for example, a part of the conductive layer 110A is removed to expose the upper surface of the inter-block structure SW. In this process, the flattening process, such as CMP is performed, using the block insulating film 133 or the like as a stopper.

Next, the process described with reference to FIG. 22 and FIG. 23, for example, is performed. Thus, the conductive layer 110 is formed.

Next, as illustrated in FIG. 24, FIG. 26, and FIG. 49, for example, the plurality of conductive layers 110 and the plurality of insulating layers 101 are formed. This process is performed by repeating the following processes: the process described with reference to FIG. 41 to FIG. 44, and FIG. 18 and FIG. 19, for example; and the process described with reference to FIG. 45 to FIG. 48, and FIG. 22 and FIG. 23.

Next, as illustrated in FIG. 30, for example, on the upper surface of the structure described with reference to FIG. 24, FIG. 26, and FIG. 49, the insulating layer 102 is formed. This process is performed by a method, such as CVD.

Next, as illustrated in FIG. 50, for example, a contact hole CCA′ is formed at the position corresponding to the contact electrode CC′. The contact hole CCA′ is a through-hole penetrating the insulating layer 102 and the insulating layer 152 and extending in the Z-direction to expose the upper surface of the conductive layer 110.

Then, as illustrated in FIG. 37 to FIG. 39, for example, the contact electrode CC′ is formed. This process is performed by a method, such as CVD.

[Third Embodiment]

[Configuration]

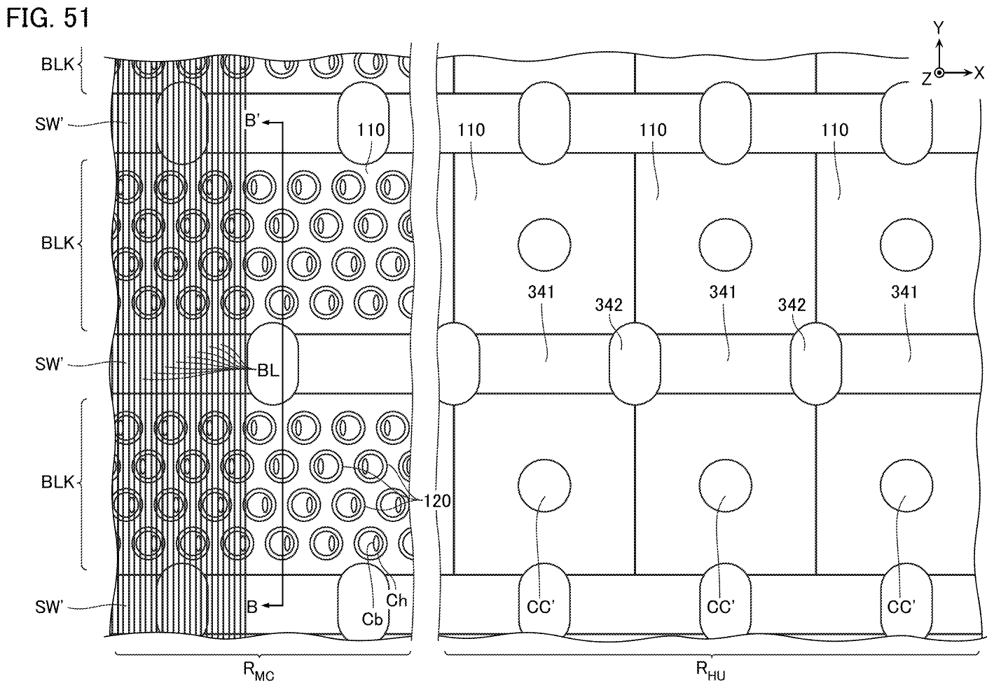

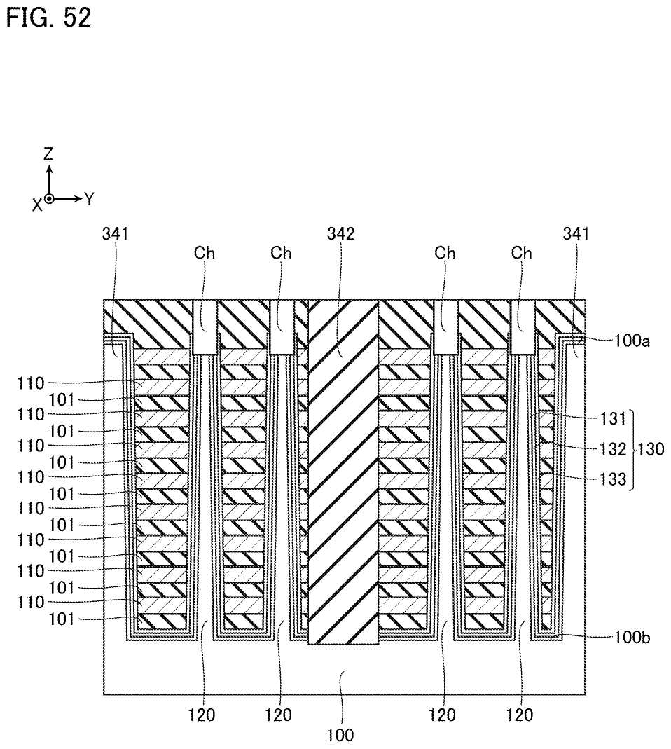

Next, with reference to FIG. 51 and FIG. 52, the configuration of the semiconductor memory device according to the third embodiment will be described. FIG. 51 is a schematic plan view to indicate a part of the configuration of the semiconductor memory device according to the third embodiment. FIG. 52 is a schematic cross-sectional view of the configuration illustrated in FIG. 51 taken along the line B-B″ and viewed along the arrow-direction.

The semiconductor memory device according to the third embodiment is basically configured similarly to the semiconductor memory device according to the second embodiment.

However, as illustrated in FIG. 51, for example, the semiconductor memory device according to the third embodiment includes an inter-block structure SW', instead of the inter-block structure SW.

The inter-block structure SW' includes a plurality of semiconductor layers 341 arranged in the X-direction and a plurality of insulating layers 342 disposed between these plurality of semiconductor layers 341.

The semiconductor layer 341 is basically configured similarly to the semiconductor layer 140. However, the length in the X-direction of the semiconductor layer 341 is shorter than the length in the X-direction of the memory block BLK.

The insulating layer 342 contains silicon oxide (SiO₂) or the like. The insulating layer 342 extends in the Z-direction as illustrated in, for example, FIG. 52 and is connected to the surface 100b of the semiconductor substrate 100 at the lower end. Also, the upper end of the insulating layer 342 is disposed above the surface 100a. Additionally, in the XY plane as illustrated in FIG. 51 and the like, the width in the Y-direction of the insulating layer 342 is greater than the width in the Y-direction of the semiconductor layer 341.

[Manufacturing Method]

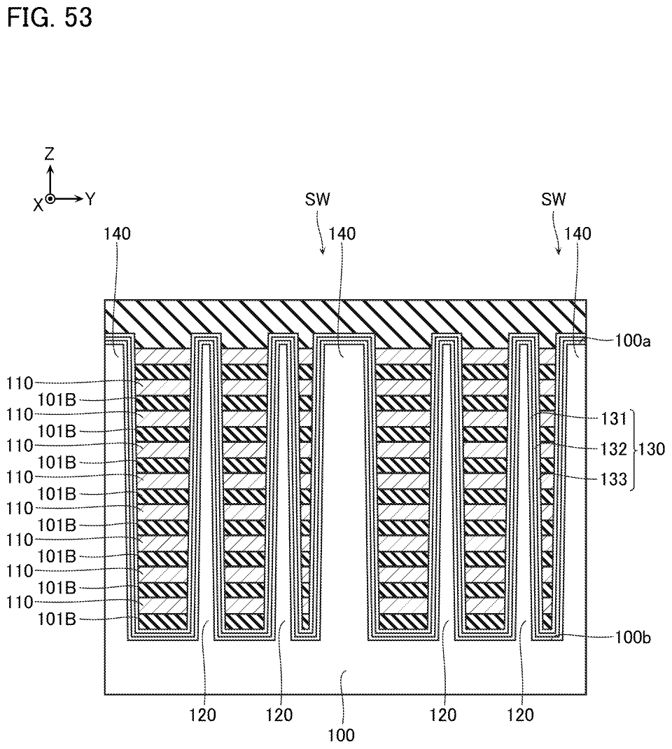

Next, with reference to FIG. 53 to FIG. 57, the manufacturing method for the semiconductor memory device according to the third embodiment will be described. FIG. 53 to FIG. 57 are schematic cross-sectional views for describing the manufacturing method, indicating the portion corresponding to FIG. 52.

In the manufacturing method, the processes similar to the processes as described with reference to FIG. 40 to FIG. 49, for example, are performed. However, in the manufacturing method, as illustrated in FIG. 53, for example, a sacrifice layer 101B is formed instead of the insulating layer 101.

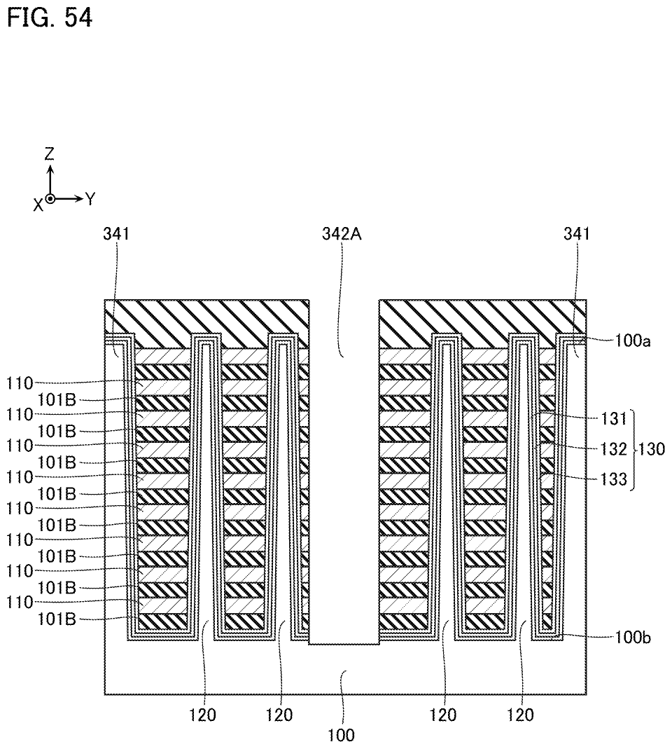

Next, as illustrated in FIG. 54, for example, a through-hole 342A is formed at the position corresponding to the insulating layer 342. The through-hole 342A is a through-hole extending in the Z-direction to expose the surface 100b of the semiconductor substrate 100. Also, the through-hole 342A separates the inter-block structure SW in the X-direction. Thus, the plurality of semiconductor layers 341 arranged in the X-direction are formed. Also, the through-hole 342A exposes the side surfaces in the Y-direction of the plurality of conductive layers 110 and of the plurality of sacrifice layers 101B arranged in the Z-direction.

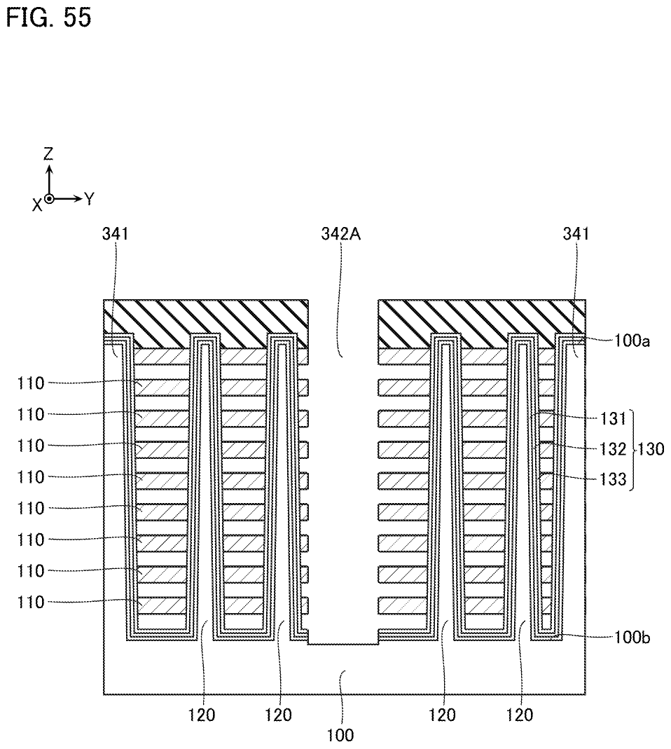

Next, as illustrated in FIG. 55, for example, the plurality of sacrifice layers 101B are removed via the through-hole 342A. This process is performed by a method, such as wet etching.

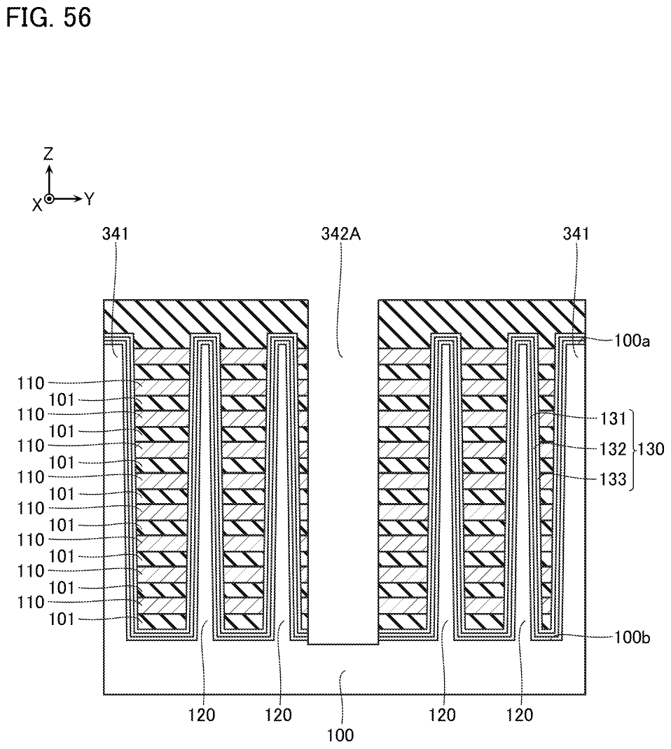

Next, as illustrated in FIG. 56, for example, the plurality of insulating layers 101 are formed. This process is performed by a method, such as CVD.

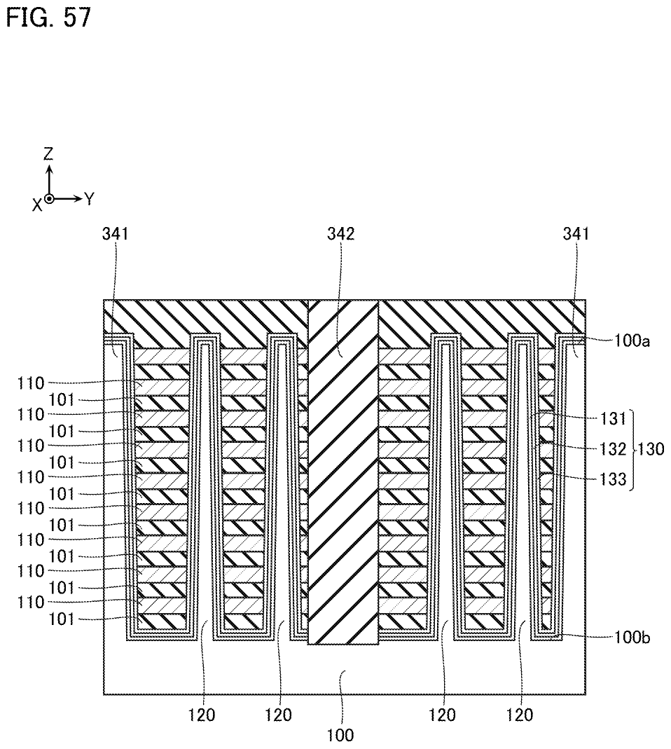

Next, as illustrated in FIG. 57, for example, the plurality of insulating layers 342 are formed. This process is performed by a method, such as CVD.

[Other Embodiments]

The semiconductor memory devices according to the first embodiment to the third embodiment have been described.

However, the semiconductor memory devices according to these embodiments are merely examples, and the specific configuration, the operation, and the like are appropriately adjustable.

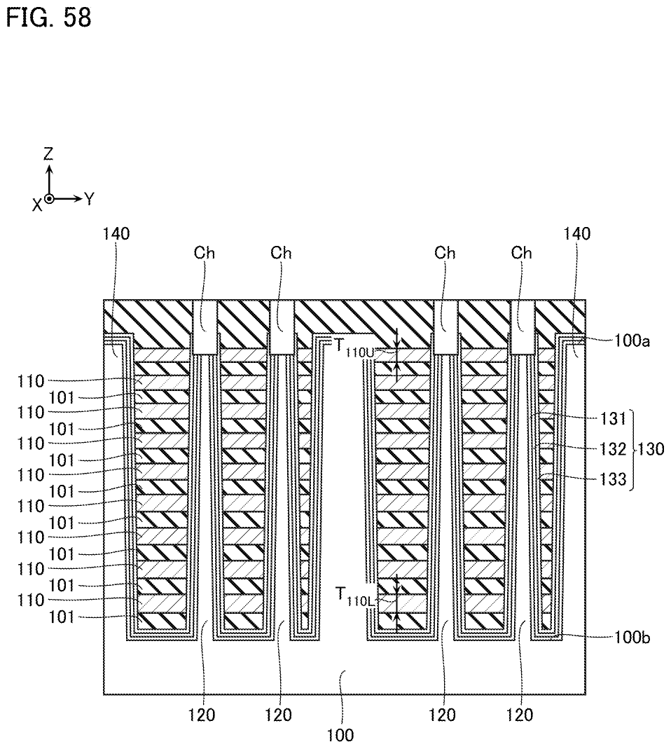

For example, in the example of FIG. 4, the plurality of conductive layers 110 arranged in the Z-direction each had a film thickness (thickness in the Z-direction) similar to one another. However, as illustrated in FIG. 58, for example, the semiconductor memory devices according to the first embodiment to the third embodiment may have a structure in which the lower the conductive layers 110 is located, the greater the film thickness (thickness in the Z-direction) is. For example, in the example of FIG. 58, a film thickness T_{110L} of the conductive layer 110 located at the lowermost layer is greater than a film thickness T_{110U} of the conductive layer 110 located at the uppermost layer.

Similarly, in the example of FIG. 4, the plurality of insulating layers 101 arranged in the Z-direction each had a film thickness (thickness in the Z-direction) similar to one another. However, as illustrated in FIG. 58, for example, the semiconductor memory devices according to the first embodiment to the third embodiment may have a structure in which the lower the insulating layers 101 is located, the greater the film thickness (thickness in the Z-direction) is.

Also, as described with reference to FIG. 4, for example, in the semiconductor memory devices according to the first embodiment to the third embodiment, the semiconductor layer 120 had an approximately columnar shape. However, such a configuration is illustrated by way of example only, and shapes of the semiconductor layer 120 are appropriately adjustable. For example, in the semiconductor memory devices according to the first embodiment to the third embodiment, the semiconductor layer 120 may have an approximately cylindroid shape, an approximately triangular columnar shape, an approximately quadrangular prism shape, or an approximately rounded corner polygon shape (such as an approximately columnar shape having a racetrack shape in the XY plane).

Also, in the semiconductor memory devices according to the first embodiment to the third embodiment, the semiconductor layers 120 are disposed at approximately regular intervals along straight lines extending at 0°, 60° and 120° with respect to the X-direction. Such an arrangement is hereinafter referred to as a staggered pattern. However, this arrangement or the like is illustrated by way of example only, and the specific arrangement is adjustable where deems appropriate. For example, the semiconductor layers 120 can be disposed at approximately regular intervals along the straight lines extending at 0° and 90° with respect to the X-direction. Such an arrangement is hereinafter referred to as a matrix pattern. Also, the semiconductor layer 120 may be disposed in other arrangements.

Also, in the example in FIG. 3 and FIG. 6, for example, the hook-up region R_{HU} had the plurality of insulating layers 151 arranged in the Y-direction. Also, the plurality of insulating layers 151 extended in the X-direction. However, such a configuration is illustrated by way of example only, shapes and arrangements for the insulating layer 151 can be adjustable where deems appropriate. For example, in the first embodiment, the hook-up region R_{HU} may include the plurality of insulating layers 151 arranged in the X-direction. Also, the plurality of insulating layers 151 in this case may be extended in the Y-direction. Also, the pattern for the insulating layers 151 in the hook-up region R_{HU} does not have to be a line and space and may be a dot pattern.

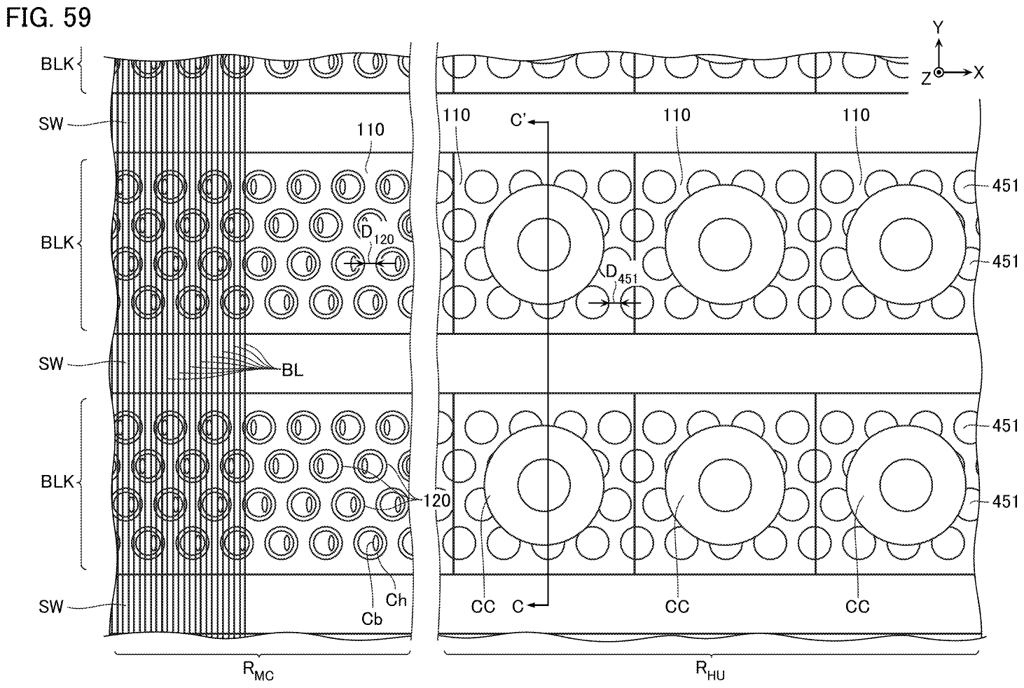

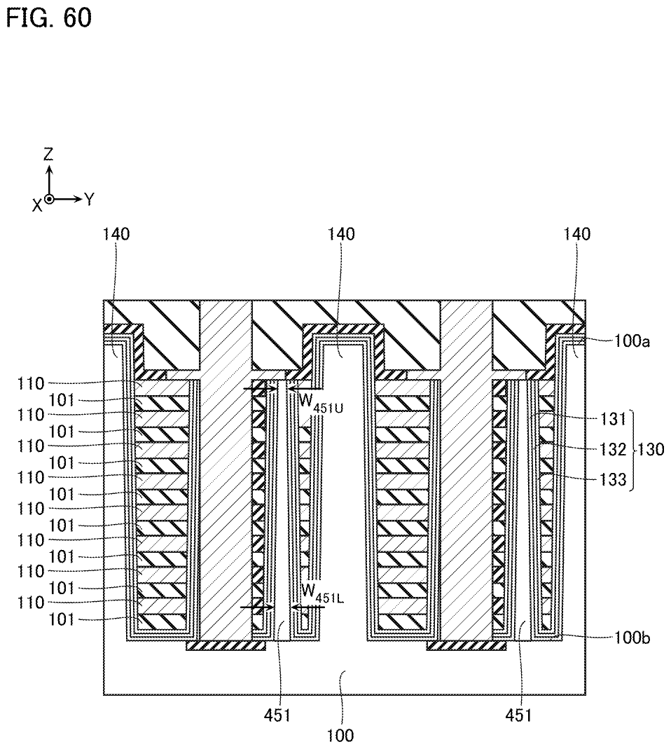

For example, in the example of FIG. 59 and FIG. 60, a plurality of insulating layers 451 are disposed in the hook-up region R_{HU}. As illustrated in FIG. 59, for example, the insulating layers 451 are arranged in the X-direction and Y-direction in a predetermined pattern. In FIG. 59, the distance between two insulating layers 451 adjacent in any of directions in the XY plane is denoted by distance D_{451.} The distance D₄₅₁ may be approximately the same as the distance D₁₂₀.

As illustrated in FIG. 60, for example, the insulating layer 451 has an approximately columnar shape. Also, the outer peripheral surfaces of the insulating layers 451 are each surrounded by the conductive layers 110, being opposed to the conductive layers 110.

The insulating layer 451 contains silicon oxide (SiO₂) or the like.

The height position of the upper end of the insulating layer 451 is, for example, approximately the same as the height position of the upper surface of any of the plurality of conductive layers 110 arranged in the Z-direction. The lower end of the insulating layer 451 is connected to the surface 100b of the semiconductor substrate 100.

The widths in the X-direction and Y-direction of the lower end portion of the insulating layer 451 may be greater than the widths in the X-direction and Y-direction of the upper end portion of the insulating layer 451. In the illustrated example, the width in the Y-direction of a portion of the insulating layer 451 opposed to the uppermost conductive layer 110, is denoted by width W_{451U}. Also, the width in the Y-direction of the portion of the insulating layer 451, opposed to the lowermost conductive layer 110, is denoted by width W_{451L}. The width W_{451L} is greater than the width W_{451U}.

Also, in the example of FIG. 59 and FIG. 60, the insulating layer 451 had an approximately columnar shape. However, such a configuration is illustrated by way of example only, shapes of the insulating layers 451 can be adjustable when deems appropriate. For example, the insulating layer 451 may have an approximately cylindroid shape, an approximately triangular columnar shape, an approximately quadrangular prism shape, or an approximately rounded corner polygon shape (such as an approximately columnar shape having a racetrack shape in the XY plane).

Also, in the example of FIG. 59 and FIG. 60, the insulating layer 451 was disposed in the staggered pattern as described above. However, such an arrangement is illustrated by way of example only, and the arrangement can be specifically adjustable when deem appropriate. For example, the insulating layer 451 may be disposed in the matrix pattern as described above or in another arrangement.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate extending in a first direction and a second direction intersecting with the first direction;
a plurality of memory blocks arranged in the first direction; and
an inter-block structure disposed between the plurality of memory blocks, wherein
the memory block includes:
a plurality of conductive layers arranged in a third direction intersecting with the first direction and the second direction, the plurality of conductive layers extending in the second direction;
a plurality of first semiconductor layers that extend in the third direction and are opposed to the plurality of conductive layers; and
a plurality of electric charge accumulating portions disposed between the plurality of conductive layers and the plurality of first semiconductor layers, wherein
the inter-block structure includes a second semiconductor layer extending in the second direction and the third direction, and
the plurality of first semiconductor layers and the second semiconductor layer are parts of the semiconductor substrate.

2. The semiconductor memory device according to claim 1, wherein
the semiconductor substrate includes a front surface and a back surface,
the front surface includes a first surface and a second surface disposed between the first surface and the back surface in the third direction, and
a surface at one side in the third direction of the second semiconductor layer is a part of the first surface.

3. The semiconductor memory device according to claim 2, wherein
positions in the third direction of the plurality of conductive layers are disposed between one end of the second semiconductor layer in the third direction and another end of the second semiconductor layer in the third direction.

4. The semiconductor memory device according to claim 1, wherein
the first semiconductor layer has:
a first width in the first direction or the second direction at a first position in the third direction; and
a second width in the first direction or the second direction at a second position in the third direction, wherein
the second position is closer to a back surface of the semiconductor substrate than the first position, and
the second width is equal to or greater than the first width.

5. The semiconductor memory device according to claim 4, wherein
the second width is greater than the first width.

6. The semiconductor memory device according to claim 1, wherein
the second semiconductor layer has:
a third width in the first direction at a third position in the third direction; and
a fourth width in the first direction at a fourth position in the third direction, wherein
the fourth position is closer to a back surface of the semiconductor substrate than the third position, and
the fourth width is equal to or greater than the third width.

7. The semiconductor memory device according to claim 6, wherein
the fourth width is greater than the third width.

8. The semiconductor memory device according to claim 1, wherein
the plurality of conductive layers include a first conductive layer and a second conductive layer,
the second conductive layer is closer to a back surface of the semiconductor substrate than the first conductive layer, and
a width of the second conductive layer in the third direction is equal to or greater than a width of the first conductive layer in the third direction.

9. The semiconductor memory device according to claim 8, wherein
the width of the second conductive layer in the third direction is greater than the width of the first conductive layer in the third direction.

10. The semiconductor memory device according to claim 1, further comprising
a first region and a second region arranged in the second direction, wherein
the first region includes:
a part of the plurality of conductive layers;
the plurality of first semiconductor layers; and
the plurality of electric charge accumulating portions, and
the second region includes:
a part of the plurality of conductive layers; and
a plurality of contact electrodes extending in the third direction and connected to the plurality of conductive layers.

11. The semiconductor memory device according to claim 10, wherein
the second region includes a plurality of first insulating layers,
the plurality of first insulating layers are arranged in at least one of the first direction and the second direction,
the plurality of first insulating layers extend in the third direction, and
the plurality of first insulating layers are connected to the plurality of conductive layers in at least one of the second direction and the first direction.

12. The semiconductor memory device according to claim 11, wherein
the first insulating layer has:
a fifth width in the first direction at a fifth position in the third direction; and
a sixth width in the first direction at a sixth position in the third direction, wherein
the sixth position is closer to a back surface of the semiconductor substrate than the fifth position, and
the sixth width is equal to or greater than the fifth width.

13. The semiconductor memory device according to claim 12, wherein
the sixth width is greater than the fifth width.

14. The semiconductor memory device according to claim 11, wherein
the plurality of contact electrodes includes a first contact electrode,
the first contact electrode includes a connection surface connected to one of the plurality of conductive layers, and
the connection surface is disposed between one end and another end of the first contact electrode in the third direction.

15. The semiconductor memory device according to claim 14, wherein
a second insulating layer is disposed between the first contact electrode and at least one of the plurality of the conductive layers closer to the semiconductor substrate than the connection surface.

16. The semiconductor memory device according to claim 14, wherein
the connection surface is connected to at least a part of the plurality of first insulating layers.

17. The semiconductor memory device according to claim 11, wherein
the plurality of first semiconductor layers include a third semiconductor layer and a fourth semiconductor layer adjacent in the second direction,
the plurality of first insulating layers include a third insulating layer and a fourth insulating layer adjacent in the second direction or the third direction, and
in a cross-sectional surface extending in the first direction and the second direction and including the third semiconductor layer, the fourth semiconductor layer, the third insulating layer, and the fourth insulating layer,
a distance between the third insulating layer and the fourth insulating layer is greater than 50% of a distance between the third semiconductor layer and the fourth semiconductor layer and smaller than 400% of the distance between the third semiconductor layer and the fourth semiconductor layer.
